(19) United States
(12) Patent Application Publication
(10) Pub. No.: US 2024/0274676 A1
(43) Pub. Date: Aug. 15, 2024

(54) SEMICONDUCTOR DEVICE INCLUDING BACKSIDE CONTACT STRUCTURE HAVING LOW OHMIC CONTACT RESISTANCE

(71) Applicant: Samsung Electronics Co., Ltd., Suwon-si (KR)

(72) Inventors: Jongjin LEE, Clifton Park, NY (US); Sooyoung PARK, Clifton Park, NY (US); Kang-ill SEO, Springfield, VA (US)

(73) Assignee: Samsung Electronics Co., Ltd., Suwon-si (KR)

(21) Appl. No.: 18/221,693

(22) Filed: Jul. 13, 2023

Related U.S. Application Data
(60) Provisional application No. 63/445,193, filed on Feb. 13, 2023.

(51) Int. Cl. H01L 29/417; H01L 21/8234; H01L 23/48; H01L 27/088; H01L 29/06; H01L 29/423; H01L 29/66; H01L 29/775; H01L 29/786

(52) U.S. Cl. CPC H01L 29/41733; H01L 21/823412; H01L 21/823418; H01L 21/823475; H01L 23/481; H01L 27/088; H01L 29/0673; H01L 29/42392; H01L 29/66439; H01L 29/66545; H01L 29/775; H01L 29/78696

(57) ABSTRACT

Provided is a semiconductor device including: a channel structure; a 1^{st} source/drain region on the channel structure; and an enlarged backside contact structure connected to the 1^{st} source/drain region, wherein the enlarged backside contact structure includes a backside contact structure below the 1^{st} source/drain region, a 1^{st} side via structure at a 1^{st} side of the 1^{st} source/drain region, and a 1^{st} front contact structure above the 1^{st} source/drain region, and wherein the backside contact structure is connected to the 1^{st} side via structure, which is connected to the front contact structure.

### CROSS-REFERENCE TO RELATED APPLICATION

This application is based on and claims priority from U.S. Provisional Application No. 63/445,193 filed on Feb. 13, 2023 in the U.S. Patent and Trademark Office, the disclosure of which is incorporated herein in its entirety by reference.

### BACKGROUND

### 1. Field

Apparatuses and methods consistent with example embodiments of the disclosure relate to a semiconductor device including at least one field-effect transistor having a backside contact structure.

### 2. Description of Related Art

Growing demand for an integrated circuit having a high device density and performance has introduced a field-effect transistor (FET) such as fin field-effect transistor (FinFET) and a nanosheet transistor. The FinFET has one or more horizontally arranged vertical fin structures as a channel structure of which at least three surfaces are surrounded by a gate structure, and the nanosheet transistor is characterized by one or more nanosheet channel layers vertically stacked on a substrate as a channel structure, and a gate structure surrounding all four surfaces of each of the nanosheet channel layers. The nanosheet transistor is referred to as gate-all-around (GAA) transistor, multi-bridge channel field-effect transistor (MBCFET)

Further, a backside power distribution network (BSPDN) structure formed at a back side of the field-effect transistor has been introduced to address a routing complexity at a back-end-of-line (BEOL) of the field-effect transistor, that is, a front side of the field-effect transistor, and prevent excessive IR drop at the front side in the field-effect transistor.

The BSPDN structure may include a backside power rail and a backside contact structure (or backside contact plug) through which a positive or negative voltage may be supplied to a source/drain region of the field-effect transistor. The backside contact structure may also be used to connect the source/drain region of the field-effect transistor to another circuit element. However, the nano-scale dimension of the back side of the field-effect transistor often causes an increased ohmic contact resistance between the source/drain region and the backside contact structure.

Information disclosed in this Background section has already been known to the inventors before achieving the embodiments of the present application or is technical information acquired in the process of achieving the embodiments described herein. Therefore, it may contain information that does not form prior art that is already known to the public.

### SUMMARY

Various example embodiments provide a semiconductor device including at least one field-effect transistor in which a backside contact structure has an enlarged footprint so that an ohmic contact resistance is reduced. The embodiments also provide a method of manufacturing the semiconductor device including the backside contact structure.

According to embodiments, there is provided a semiconductor device which may include: a channel structure; a 1^{st} source/drain region on the channel structure; and an enlarged backside contact structure connected to the 1^{st} source/drain region, wherein the enlarged backside contact structure includes a backside contact structure below the 1^{st} source/drain region, a 1^{st} side via structure at a 1^{st} side of the 1^{st} source/drain region, and a 1^{st} front contact structure above the 1^{st} source/drain region, and wherein the backside contact structure is connected to the 1^{st} side via structure, which is connected to the front contact structure.

According to embodiments, the backside contact structure may be connected to a bottom surface of the 1^{st} source/drain region, the 1^{st} side via structure may be connected to a 1^{st} side surface of the 1^{st} source/drain region, and the front contact structure may be connected to a top surface of the 1^{st} source/drain region.

According to embodiments, the enlarged backside contact structure may further include a 2^{nd} side via structure at a 2^{nd} side, opposite to the 1^{st} side, of the 1^{st} source/drain region, wherein the 2^{nd} side via structure is connected to a 2^{nd} side surface, opposite to the 1^{st} side surface, of the 1^{st} source/drain region.

According to an embodiment, there is provided a semiconductor device which may include: a channel structure: a 1^{st} source/drain region on the channel structure; and an enlarged backside contact structure connected to the 1^{st} source/drain region, wherein the enlarged backside contact structure contacts at least a bottom surface and a 1^{st} side surface of the 1^{st} source/drain region.

According to an embodiment, there is provided a method of manufacturing a semiconductor device, which may include providing a channel structure on a substrate; forming a placeholder structure in the substrate at a position where a source/drain region is to be formed thereabove; forming the source/drain region above the placeholder structure; forming a 1^{st} side via structure contacting a 1^{st} side surface of the source/drain region; and replacing the placeholder structure with a backside contact structure contacting a bottom surface of the source/drain region, and connected to the 1^{st} side via structure.

### BRIEF DESCRIPTION OF DRAWINGS

Example embodiments of the disclosure will be more clearly understood from the following detailed description taken in conjunction with the accompanying drawings in which:

FIG. 1A-1E illustrates a semiconductor device including a plurality of nanosheet transistors in which an enlarged backside contact structure is formed on a source/drain region, according to an embodiment;

FIG. 2A-2E illustrates a semiconductor device including a plurality of nanosheet transistors in which an enlarged backside contact structure is formed on a source/drain region, according to an embodiment;

FIGS. 3A-3D to 24A-24E illustrate intermediate semiconductor devices after respective operations the process of manufacturing the semiconductor are performed, according to embodiments;

FIG. 25 is a flowchart illustrating a method of manufacturing a semiconductor device including a plurality of field-effect transistors in which an enlarged backside contact structure is formed on a source/drain region, according to embodiments; and

FIG. 26 is a schematic block diagram illustrating an electronic device including a plurality of field-effect transistors in which an enlarged backside contact structure is formed on a source/drain region, as shown in FIGS. 1A-1E or FIGS. 2A-2E, according to an example embodiment.

### DETAILED DESCRIPTION OF EMBODIMENTS

The embodiments of the disclosure described herein are example embodiments, and thus, the disclosure is not limited thereto, and may be realized in various other forms. Each of the embodiments provided herein is not excluded from being associated with one or more features of another example or another embodiment also provided herein or not provided herein but consistent with the disclosure. For example, even if matters described in a specific example or embodiment are not described in a different example or embodiment thereto, the matters may be understood as being related to or combined with the different example or embodiment, unless otherwise mentioned in descriptions thereof. In addition, it is to be understood that all descriptions of principles, aspects, examples, and embodiments of the disclosure are intended to encompass structural and functional equivalents thereof. In addition, these equivalents should be understood as including not only currently well-known equivalents but also equivalents to be developed in the future, that is, all devices invented to perform the same functions regardless of the structures thereof.

It is to be understood that when an element, component, layer, pattern, structure, region, or so on (hereinafter collectively “element”) of a semiconductor device is referred to as being “over,” “above,” “on,” “below,” “under,” “beneath,” “connected to” or “coupled to” another element the semiconductor device, it can be directly over, above, on, below, under, beneath, connected or coupled to the other element or an intervening element(s) may be present. In contrast, when an element of a semiconductor device is referred to as being “directly over,” “directly above,” “directly on,” “directly below,” “directly under,” “directly beneath,” “directly connected to” or “directly coupled to” another element of the semiconductor device, there are no intervening elements present. Like numerals refer to like elements throughout this disclosure.

Spatially relative terms, such as “over,” “above,” “on,” “upper,” “below,” “under,” “beneath,” “lower,” “left,” “right,” “lower-left,” “lower-right,” “upper-left,” “upper-right,” “central,” “middle,” and the like, may be used herein for ease of description to describe one element's relationship to another element(s) as illustrated in the drawings. It is to be understood that the spatially relative terms are intended to encompass different orientations of a semiconductor device in use or operation in addition to the orientation depicted in the drawings. For example, if the semiconductor device in the drawings is turned over, elements described as “below” or “beneath” other elements would then be oriented “above” the other elements. Thus, the term “below” can encompass both an orientation of above and below. The semiconductor device may be otherwise oriented (rotated 90 degrees or at other orientations) and the spatially relative descriptors used herein interpreted accordingly. As another example, when elements referred to as a “lower” element and an “upper” element” may be an “upper” element and a “lower” element when a device or structure including these elements are differently oriented. Thus, in the descriptions herebelow, the “lower” element and the “upper” element may also be referred to as a “1^{st}” element or a “2^{nd}” element, respectively, as long as their structural relationship is clearly understood in the context of the descriptions. Similarly, the terms a “left” element and a “right” element may be respectively referred to as a “1^{st}” element and a “2^{nd}” element with necessary descriptions to distinguish the two elements.

It is to be understood that, although the terms “1^{st},” “2^{nd},” “3^{rd},” “4^{th},” “5^{th},” “6^{th},” etc. may be used herein to describe various elements, these elements should not be limited by these terms. These terms are only used to distinguish one element from another element. Thus, a 1^{st} element described in one embodiment herein could be termed a 2^{nd} element in another embodiment or claims of the disclosure without departing from the teachings of the disclosure.

As used herein, expressions such as “at least one of,” when preceding a list of elements, modify the entire list of elements and do not modify the individual elements of the list. For example, the expression, “at least one of a, b and c,” should be understood as including only a, only b, only c, both a and b, both a and c, both b and c, or all of a, b and c. Herein, when a term “same” is used to compare a dimension of two or more elements, the term may cover a “substantially same” dimension.

It is to be understood that various elements shown in the drawings are schematic illustrations not drawn to scale. In addition, for ease of explanation, one or more elements of a type commonly used to form semiconductor devices may not be explicitly shown in the drawings without implying these elements are omitted from actual semiconductor devices. Furthermore, it is to be understood that the embodiments described herein are not limited to particular materials, features, and manufacturing steps or operations shown or described herein. Thus, with respect to semiconductor manufacturing steps, the descriptions provided herein are not intended to include all steps that may be required to form an actual semiconductor device. For example, the commonly-used steps such as planarizing, cleaning, or annealing steps may not be described herein for the sake of brevity. It is to be also understood that, even if a certain step or operation is described later than another step or operation, the step or operation may be performed later than the other step or operation unless the other step or operation is described as being performed after the step or operation.

Many embodiments are described herein with reference to cross-sectional views that are schematic illustrations of the embodiments. As such, variations from the shapes of the illustrations as a result, for example, of manufacturing techniques and/or tolerances, are to be expected. Thus, the embodiments should not be construed as limited to the particular shapes of elements illustrated herein but are to include deviations in shapes that result, for example, from manufacturing. Various elements illustrated in the drawings are schematic in nature and their shapes are not intended to illustrate the actual shape of an element of a semiconductor device and are not intended to limit the scope of the disclosure.

Moreover, functions, materials and shapes of conventional elements of semiconductor devices including a semiconductor device may not be described when these elements are not related to the novel features of the embodiments or not necessary in describing the same.

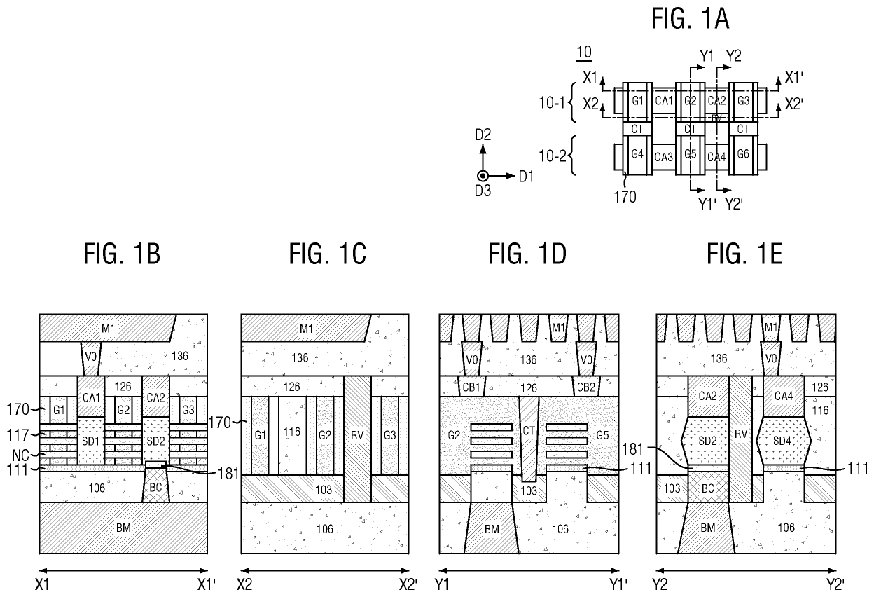

Herebelow, various embodiments of the disclosure will be described in reference to FIGS. 1A-1E to FIGS. 24A-24E.

FIG. 1A-1E illustrates a semiconductor device including a plurality of nanosheet transistors in which an enlarged backside contact structure is formed on a source/drain region, according to an embodiment. FIG. 1A is a top plan view of the semiconductor device, and FIGS. 1B-1E are cross-section views of the semiconductor device of FIG. 1A taken along lines X1-X1′, X2-X2′, Y1-Y1′ and Y2-Y2′ shown in FIG. 1A, respectively.

It is to be understood that FIG. 1A is provided to help understanding of a positional relationship of contact structures according to the present embodiment with respect to a gate structure and source/drain regions of a semiconductor device, and thus, some elements of the semiconductor device such as a channel structure, BEOL metal lines and contact structures shown in FIGS. 1B-1E are not shown in FIG. 1A.

Referring to FIG. 1A, a semiconductor device 10 may include a 1^{st} semiconductor cell 10-1 and a 2^{nd} semiconductor cell 10-2 arranged in a 2^{nd} direction D2, which is a channel-width direction, intersecting a 1^{st} direction D1 which is a channel-length direction of a current flow between source/drain regions of a transistor.

The 1^{st} semiconductor cell 10-1 may include a 1^{st} nanosheet transistor TR1 (to be shown in FIG. 1A) which includes a 1^{st} source/drain region SD1 and a 2^{nd} source/drain region SD2 connected to each other by a 2^{nd} channel structure CH2 surrounded by a 2^{nd} gate structure. The 2^{nd} semiconductor cell 10-2 may include a 2^{nd} nanosheet transistor TR2 (to be shown in FIG. 1A) which includes a 3^{rd} source/drain region SD3 and a 4^{th} source/drain region SD4 connected to each other by a 5^{th} channel structure CH5 surrounded by a 5^{th} gate structure. It is to be understood here that the channel structures CH2 and CH5 disposed below the gate structures G2 and G5, respectively, are not shown in FIG. 1A, which is a top plan view of the semiconductor device 10.

Although FIG. 1A shows two semiconductor cells 10-1 and 10-2, there may be more than two semiconductor cells arranged in the semiconductor device 10 in the 2^{nd} direction D2. Further, although FIG. 1A shows that one nanosheet transistor is included in each of the semiconductor cells 10-1 and 10-2, there may be more than one nanosheet transistor arranged in each of the semiconductor cells 10-1 and 10-2 in the 1^{st} direction D1. For example, the source/drain regions SD1-SD4 may form other nanosheet transistors with gate structures G1, G3, G4 and G6 and channel structures respectively surrounded by these gate structures at sides of the nanosheet transistors TR1 and TR2.

Each of the channel structures CH2 and CH5 of the respective nanosheet transistor TR1 and TR2 may include a plurality of nanosheet layers NC, as channel layers, surrounded by a corresponding gate structure and connecting corresponding source/drain regions, as shown in FIGS. 1B and 1D. For example, the nanosheet layers NC of the 2^{nd} channel structure CH2 may connect the 1^{st} source/drain region SD1 to the 2^{nd} source/drain region SD2 so that a current flows therebetween under the control of the 2^{nd} gate structure G2 surrounding the nanosheet layers NC. The nanosheet layers NC may each be formed of a material such as silicon (Si), for example.

The gate structures G2 and G5 may each include a gate dielectric layer, a work-function layer and a gate electrode. The gate dielectric layer formed on the nanosheet layers NC may include a dielectric material such as hafnium oxide (e.g., HfO₂). The work-function layer formed on the gate dielectric layer may include a material such as titanium (Ti), tantalum (Ta), etc., not being limited thereto, which may differ by polarity type of a transistor to form. The gate electrode surrounding the work-function layer may include one or more metal components or metal compound including copper (Cu), aluminum (Al), tungsten (W), molybdenum (Mo), ruthenium (Ru), cobalt (Co), etc., not being limited thereto.

On the gate structures G2 and G5, there may be formed 1^{st} and 2^{nd} gate contact structures CB1 and CB2 to receive gate input signals through via structures V0 and metal lines M1, respectively, which are formed above the nanosheet transistors TR1 and TR2. The gate contact structures CB1 and CB may contact top surfaces of the gate structures G2 and G5, respectively, for example. The gate contact structures CB1, CB2, the via structures V0 and the metal lines M1 may be formed of one or more metal components or metal compound including copper (Cu), aluminum (Al), tungsten (W), molybdenum (Mo), ruthenium (Ru), cobalt (Co), etc., not being limited thereto.

The source/drain regions SD1-SD4 may be formed of silicon (Si) or silicon germanium (SiGe) doped with impurities such as boron (B), gallium (Ga), indium (In), phosphorus (P), arsenic (As), antimony (Sb), etc. depending on a polarity type of a transistor to form. For example, a p-type source/drain region may include silicon germanium (SiGe) doped with impurities such as boron (B), while an n-type source/drain region may include silicon (Si) doped with phosphorus (P).

Among the source/drain regions SD1-SD4, the 1^{st}, 3^{rd} and 4^{th} source/drain regions SD1, SD3 and SD4 may be connected to a voltage source or other circuit elements of the semiconductor device 10 through 1^{st}, 3^{rd} and 4^{th} front contact structures CA1, CA3 and CA4, the via structures V0 and the metal lines M1, respectively. The front contact structures CA1, CA3 and CA4 may contact top surfaces of the source/drain regions SD1, SD3 and SD4, respectively, for example.

According to an embodiment, however, the 2^{nd} source/drain region SD2 may be connected to a voltage source of another circuit element through a backside contact plug BC combined with a 2^{nd} front contact structure CA2 and a side via structure RV, and the backside contact plug BC may be connected to a backside metal line BM, as shown in FIG. 1E. That is, the 2^{nd} source/drain region SD2 may be connected to the backside metal line BM through an enlarged backside contact structure. The backside metal line BM may be a backside power rail, for example.

According to an embodiment, the 2^{nd} front contact structure CA2, the side via structure RV and the backside contact structure BC may contact a top surface, a side surface at a side of the channel-width direction, and a bottom surface of the 2^{nd} source/drain region SD2, respectively, and connected to each other in the semiconductor device 10, as shown in FIGS. 1A and 1E. According to an embodiment, the side via structure RV may also contact side surfaces of the front contact structure CA2 and the backside contact structure BC.

According to an embodiment, the contacts between the 2^{nd} source/drain region SD2, the front contact structure CA2 and the side via structure RV may be direct contacts, except that the 2^{nd} source/drain region SD2 may contact the backside contact structure BC through a buffer layer 181 to be discussed later.

Thus, although the 2^{nd} source/drain region SD2 may be connected to the backside metal line BM2 at a back side of the second nanosheet transistor TR2, a contact area of the 2^{nd} source/drain region SD2 may be increased, and an ohmic contact resistance of the 2^{nd} source/drain region SD2 may be reduced due to the enlarged backside contact structure formed by combining the backside contact structure BC with the side via structure RV and the 2^{nd} front contact structure CA2.

According to an embodiment, the enlarged backside contact structure may include the backside contact structure BC and the side via structure RV without the front contact structure CA2 to, for example, simplify the structure of the semiconductor device 10. Even without the front contact structure CA2, the backside contact structure BC may still be enlarged by the side via structure RV to increase the contact area of the 2^{nd} source/drain regions SD2 and reduce the ohmic contact resistance of the 2^{nd} source/drain region SD2.

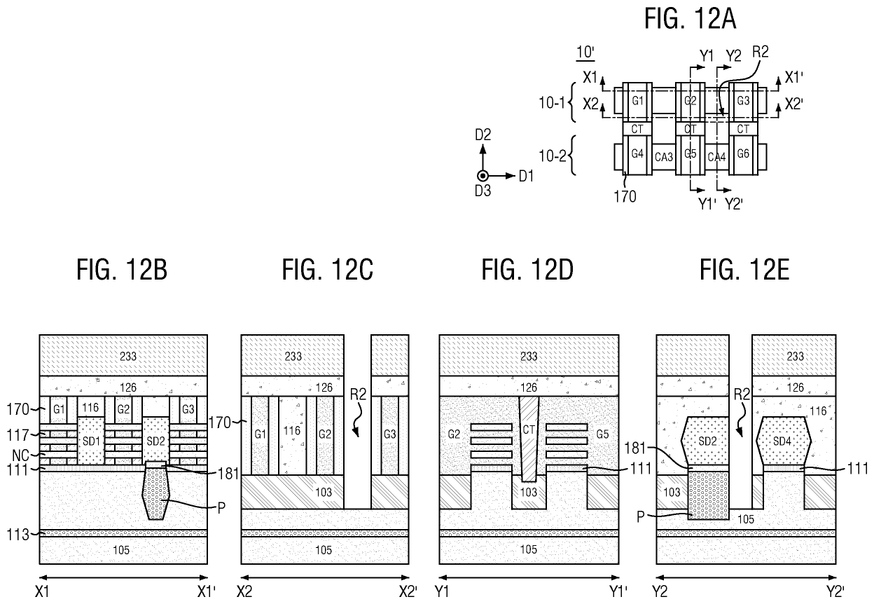

According to an embodiment, the 2^{nd} source/drain region SD2 connected to the enlarged backside contact structure may take a shape different from the other source/drain region SD1, SD3 and SD4 connected to the front contact structures CA1, CA3 and CA4, respectively. This is because the side surface of the 2^{nd} source/drain region SD2 contacting the side via structure RV of the enlarged backside contact structure may have been cut during the formation of the side via structure RV, as will be described later in reference to FIGS. 12A-12E to 16A-16E. Thus, the shape of this side surface of the 2^{nd} source/drain regions SD2 may be vertically plane, which may be different from that of the opposite side in the channel-width direction.

According to an embodiment, an entirety of one side surface of each of the front contact structure CA2, the 2^{nd} source/drain region, and the backside contact structure BC may contact the side via structure RV in the Y2-Y2′ cross-section view. According to an embodiment, bottom surfaces of the side via structure RV and the backside contact structure BC may be coplanar.

The front contact structures CA1-CA4, the side via structure RV and the backside contact structure BC may be formed of one or more metal components or metal compound including copper (Cu), aluminum (Al), tungsten (W), molybdenum (Mo), ruthenium (Ru), cobalt (Co), etc., not being limited thereto.

The front contact structures CA1-CA4 and the gate contact structures CB1, CB2 may be referred to as middle-of-line (MOL) contact structures, and the metal lines B1 may be referred to as BEOL metal lines.

According to an embodiment, a buffer layer 181 may be formed between the 2^{nd} source/drain region and the backside contact structure BC, as shown in FIGS. 1B and 1E. A side surface of the buffer layer 181 between the 2^{nd} source/drain region SD2 and the backside contact structure may also contact the side via structure RV.

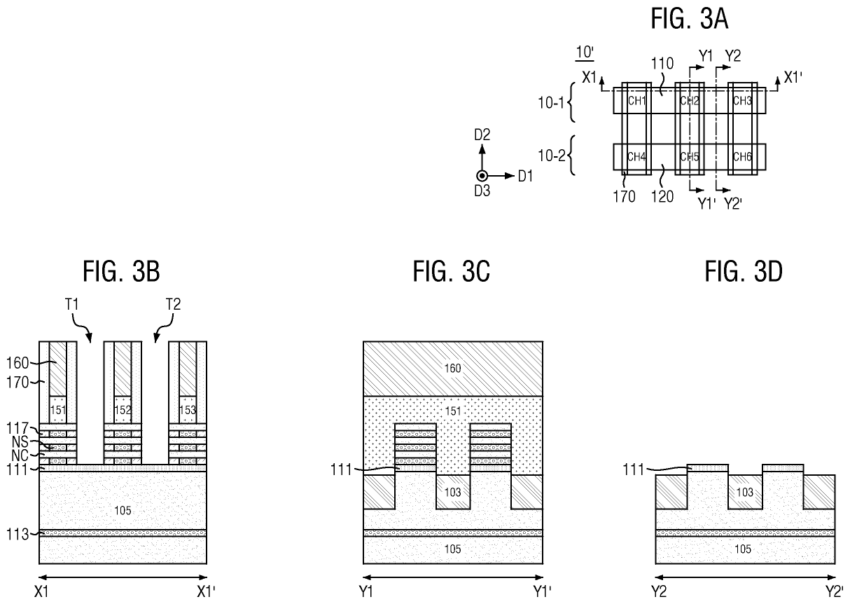

As will be describe later in describing a method of manufacturing the semiconductor device 10 in reference to FIGS. 3A-3D to 24A-24E, the buffer layer 181 may be formed at a region where a portion of a base diffusion isolation (BDI) layer 111 is removed. The buffer layer 181 may be used to protect a material loss that may occur in the formation of the backside contact structure BC, and further, may be used control an ohmic contact resistance of the 2^{nd} source/drain region for the 1^{st} nanosheet transistor TR1 in the semiconductor device 10.

The remaining BDI layer 111 may be formed at bottom surfaces of the 1^{st} and 4^{th}source/drain regions SD1 and SD4 and the gate structures G2 and G5 connected to the metal lines M1 formed above the nanosheet transistors TR1 and TR2. The BDI layer 111 may prevent current leakage from these active regions to a backside isolation structure 106 to be described below. The BDI layer may be formed of a material such as silicon nitride, silicon carbon nitride (SiCN) or silicon boron carbon nitride (SiBCN), not being limited thereto, and the buffer layer 181 may be formed of silicon (Si) which is not doped with impurities.

According to an embodiment, the semiconductor device 10 may include a plurality of isolation structures. It is to be understood here that the term “isolation” may refer to electrical insulation.

A shallow trench isolation (STI) structure 103 may be formed below a level of a bottom surface of the channel structures CH1-CH6 between the two semiconductor cells 10-1 and 10-2 to isolate active regions of the 1^{st} semiconductor cell 10-1 from those of the 2^{nd} semiconductor cell 10-2. The STI structure 103 may be formed of a material including silicon oxide (e.g., SiO, SiO₂, etc.).

A gate-cut structure CT may isolate the 1^{st} to 3^{rd} gate structures G1-G3 from the 4^{th} to 6^{th} gate structures G4-G6. For example, the gate-cut structure CT along with the STI structure 103 may isolate the 1^{st} nanosheet transistor TR1 including the 1^{st} gate structure G2 from the 2^{nd} nanosheet transistor TR2 including the 5^{th} gate structure G5.

A 1^{st} isolation structure 116 may isolate the 1^{st} and 2^{nd} source/drain regions SD1 and SD2 of the 1^{st} nanosheet transistor TR1 from other circuit elements including the 3^{rd} and 4^{th} source/drain regions SD3 and SD4 of the 2^{nd} nanosheet transistors TR2. A 2^{nd} isolation structure 126 formed above the 1^{st} isolation structure 116 may isolate the front contact structures CA1-C4 from each other. A 3^{rd} isolation structure 135 formed above the 2^{nd} isolation structure 126 may isolate the via structures V0 and the metal lines M1 from one another. The backside isolation structure 106 which may be formed by replacing at least a portion of a substrate of the semiconductor device 10 may isolate the backside contact structure BC and the backside metal line BM from each other and from other circuit elements including other backside contact structures and backside metal lines formed at the backside of the semiconductor device 10. The isolation structures 116, 126, 136 and 106 may be formed of a same or similar material including silicon oxide (e.g., SiO, SiO₂, etc.). The isolation structures 115, 125, 136 and 106 may each be referred to as an interlayer dielectric layer (ILD) structure.

An inner spacer 117 may be formed at sides of a portion of each of the gate structures G1-G6 between the nanosheet layers NC of a corresponding channel structure as shown in FIG. 1B. The inner spacer 117 may isolate a corresponding gate structure from corresponding source/drain regions. For example, the inner spacer 117 isolate a portion the 2^{nd} gate structure G2 between the nanosheet layers NC of the 2^{nd} channel structure CH2 from each of the source/drain regions SD1 and SD2. The inner spacer 117 may be formed of a material such as silicon nitride (e.g., SiN, Si₃N₄, etc.), not being limited thereto.

A gate spacer 170 may be formed between side surfaces of each of the gate structures G1-G6 and the 1^{st} isolation structure 116 as shown in FIG. 1C. The gate spacers 170 may also isolate each gate structure from the front contact structures CA1-CA4. The gate spacer 170 may be formed of a material such as silicon oxide (e.g., SiO, SiO₂, etc.) or silicon nitride (e.g., SiN, Si₃N₄, etc.). According to an embodiment, as shown in FIG. 1C, the side via structure RV forming the enlarged backside contact structure may be formed between the gate spacer 170 at a side surface of the 2^{nd} gate structure G2 and the gate spacer 170 at a side surface of the 3^{rd} gate structure.

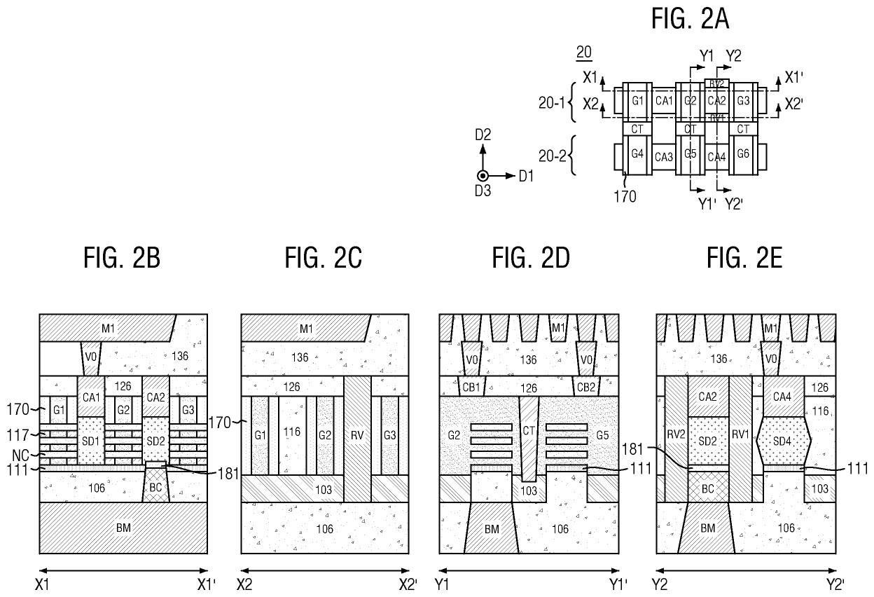

FIG. 2A-2E illustrates a semiconductor device including a plurality of nanosheet transistors in which an enlarged backside contact structure is formed on a source/drain region, according to an embodiment. FIG. 2A is a top plan view of the semiconductor device, and FIGS. 2B-2E cross-section views of the semiconductor device of FIG. 1A along lines X1-X1′, X2-X2′, Y1-Y1′ and Y2-Y2′ shown in FIG. 2A, respectively.

Referring to FIGS. 2A-2E, a semiconductor device 20 may include a plurality of semiconductor cells including a 1^{st} semiconductor cell 20-1 and a 2^{nd} semiconductor cell 20-2. The semiconductor device 20 may include the same structural elements as those included in the semiconductor device 10 of FIGS. 1A-1E except an enlarged backside contact structure. Thus, duplicate descriptions are omitted, and only a different aspect of the semiconductor device 20 is described herebelow.

According to an embodiment, as shown in FIG. 2E, the semiconductor device 20 may also include an enlarged backside contact structure connecting a 2^{nd} source/drain region SD2 of a 1^{st} nanosheet transistor TR1 to a backside metal line BM. However, the enlarged backside contact structure according to the present embodiment may take a further enlarged form by combining a backside contact structure BC with a 2^{nd} front contact structure CA2, a 1^{st} side via structure RV1 and a 2^{nd} side via structure RV2. The 2^{nd} side via structure RV2 may be formed at an opposite side of the side where the 1^{st} side via structure RV2 is formed with respect to the 2^{nd} source/drain region SD2 in the channel-width direction, as shown in FIGS. 2A and 2E. The 1^{st} side via structure RV1 may be the same as the side via structure RV included in the semiconductor device 10 of FIGS. 1A-1E.

According to an embodiment, the 2^{nd} front contact structure CA2, the side via structures RV1 and RV2, and the backside contact structure BC may contact the 2^{nd} source/drain region SD2 at a top surface, two opposite side surfaces in the channel-width direction, and a bottom surface, respectively, and connected to each other in the semiconductor device 20. Thus, FIG. 2E shows that four sides of the 2^{nd} source/drain region SD2 contacts the enlarged backside contact structure in a cross-section view. According to an embodiment, the side via structures RV1 and RV2 may contact both side surfaces of the 2^{nd} front contact structure CA2, both side surfaces of the 2^{nd} source/drain region SD2, and both side surfaces of the buffer layer 181, and both side surfaces of the backside contact structure BC, in a cross-section view of FIG. 2E. Accordingly, a contact area of the 2^{nd} source/drain region SD2 in the semiconductor device 20 may be further increased, and an ohmic contact resistance of the 2^{nd} source/drain region SD2 may be further reduced due to the enlarged backside contact structure shown in FIGS. 2A, 2C and 2E.

According to an embodiment, the enlarged backside contact structure may include the backside contact structure BC and the side via structures RV1 and RV2 without the front contact structure CA2 to, for example, simplify the structure of the semiconductor device 20. Even without the front contact structure CA2, the backside contact structure BC is still enlarged by the side via structures RV1 and RV2 to increase the contact area of the 2^{nd} source/drain regions SD2 and reduce the ohmic contact resistance of the 2^{nd} source/drain region SD2 in the semiconductor device 20.

According to an embodiment, the 2^{nd} source/drain region SD2 of the semiconductor device 20 connected to the enlarged backside contact structure may take a shape different from the other source/drain region SD1, SD3 and SD4 of the semiconductor device 20 connected to the front contact structures CA1, CA3 and CA4, respectively. This is because the two side surfaces of the 2^{nd} source/drain region SD2 contacting the side via structures RV1 and RV2 of the enlarged backside contact structure may have been cut during the formation of the side via structures RV1 and RV2, respectively. Thus, the shapes of these two side surfaces of the 2^{nd} source/drain regions SD2 of the semiconductor device 20 may be both vertically plane, for example.

Herebelow, a process of manufacturing a semiconductor device including a plurality of nanosheet transistors in which an enlarged backside contact structure is formed on a source/drain region, according to an embodiment in reference to FIGS. 3A-3D to 24A-24E.

FIGS. 3A-3D to 24A-24E illustrate intermediate semiconductor devices after respective operations the process of manufacturing the semiconductor are performed, according to embodiments.

FIGS. 3A to 24A are top plan views of the intermediate semiconductor devices, and FIGS. 3B-3D to FIGS. 24B-24E are respective cross-section views of the intermediate semiconductor devices taken along lines X1-X1′, X2-X2′, Y1-Y1′ and Y2-Y2′ shown in FIGS. 3A to 24A, respectively

It is to be understood that FIGS. 3A to 24A are provided to help understanding of a positional relationship of contact structures to be formed according to embodiments with respect to a fin structure, a dummy gate structure, a gate structure and source/drain regions of an intermediate semiconductor device, and thus, not all of the structural elements of the intermediate semiconductor device may be shown.

The semiconductor device manufactured herein may be or correspond to the semiconductor device 10 shown in FIGS. 1A-1E. As each of the intermediate semiconductor devices 10′ shown in FIGS. 3A-3D to 24A-24E may be a base structure from which the semiconductor device 10 shown in FIGS. 1A-1E described above is manufactured, elements the same as or similar to the elements included in the semiconductor device 10 may be included in one or more of the intermediate semiconductor devices described herebelow with the same reference numbers. Thus, duplicate descriptions thereof may be omitted herebelow.

Referring to FIGS. 3A-3D, an intermediate semiconductor device 10′ may include a 1^{st} semiconductor cell 10-1 and a 2^{nd} semiconductor cell 10-2 arranged in the 2^{nd} direction D2. The 1^{st} semiconductor cell 10-1 and the 2^{nd} semiconductor cell 10-2 may include a 1^{st} fin structure 110 and a 2^{nd} fin structure 110 formed on a substrate 105, and extended in the 1^{st} direction D1, respectively. The 1^{st} fin structure 110 may be spaced apart from the 2^{nd} fin structure 120 in the 2^{nd} direction D2 by an STI structure 103.

1^{st} trench T1 and a 2^{nd} trench T2 may be formed on the substrate 105 to divide a dummy gate structure formed on the 1^{st} and 2^{nd} fin structures 110 and 120 into 1^{st} to 3^{rd} dummy gate structures 151-153 respectively extended in the 2^{nd} direction D2. The two trenches T1 and T2 along with the STI structures 103 may also divide the 1^{st} and 2^{nd} fin structures 110 and 120 into 1^{st} to 6^{th} channel structures CH1-CH6. Thus, the 1^{st} dummy gate structure 151 may surround the 1^{st} and 4^{th} channel structures CH1 and CH4, the 2^{nd} dummy gate structure 152 may surround the 2^{nd} and 5^{th} channel structures CH2 and CH5, and the 3^{rd} dummy gate structure 153 may surround the 3^{rd} and 6^{th} channel structures CH3 and CH6.

The dummy gate structure is referred to as such as they are to be replaced by a replacement metal gate (RMG) structure to form each of the gate structures G1-G6 shown in FIGS. 1A-1E, in a later step of manufacturing a semiconductor device. The dummy gate structure may be formed of polycrystalline silicon (p-Si), for example.

Each of the channel structures CH1-CH6 may include a plurality of nanosheet layers NC on a plurality of sacrificial layers NS, respectively. The nanosheet layers NC, formed of, for example, silicon (Si), are referred to as channel layers as they are to function as current paths between source/drain regions when a semiconductor device is completed to include a plurality of nanosheet transistors formed of the channel structures CH1-CH6. The sacrificial layers NS, formed of, for example, silicon germanium (SiGe), are referred to as such as they, along with the dummy gate structures 151-153, will be replaced by the RMG structure after source/drain regions of the nanosheet transistors are formed in a semiconductor device in a later step.

Abase diffusion isolation (BDI) layer 111 may be formed on the substrate 105 to isolate the substrate 105 from gate structures and source/drain regions to be formed in a later step so that current leakage from these structures may be prevented. The BDI layer 111 may include silicon nitride, silicon carbon nitride (SiCN) or silicon boron carbon nitride (SiBCN), not being limited thereto.

A gate hard mask structure 160 which was used to form the dummy gate structures 151-153 may remain on each of the dummy gate structures 151-153 at this step of manufacturing a semiconductor device.

An inner spacer 117 may be formed at both sides of each of the sacrificial layers NS in the 1^{st} direction to isolate the sacrificial layer NS from source/drain regions to be formed in a later step. A gate spacer 170 may be formed at both side surfaces of each of the dummy gate structures 151-153 to isolate the dummy gate structure 151-153 from other structural elements in the intermediate semiconductor device 10′. The gate spacer 170 may also be extended in a 3^{rd} direction D3 to be formed at side surfaces of the gate hard mask structure 160 on each of the dummy gate structure 151-153. The 3^{rd} direction D3 may intersect or may be perpendicular to the 1^{st} and 2^{nd} directions D1 and D2. Further, an etch stop layer 113 may be formed in the substrate 105 at a predetermined level from a bottom surface of the substrate 105 to control a depth of etching applied to the substrate in a later step.

FIGS. 3A-3D show that the intermediate semiconductor device 10′ includes two fin structures divided into six channel structures, each of which has three channel layers, and three dummy gate structures surrounding the six channel structures. However, these numbers of the structural elements are an example. Thus, more or less than those numbers of the structural elements may form the intermediate semiconductor device 10′, according to embodiments.

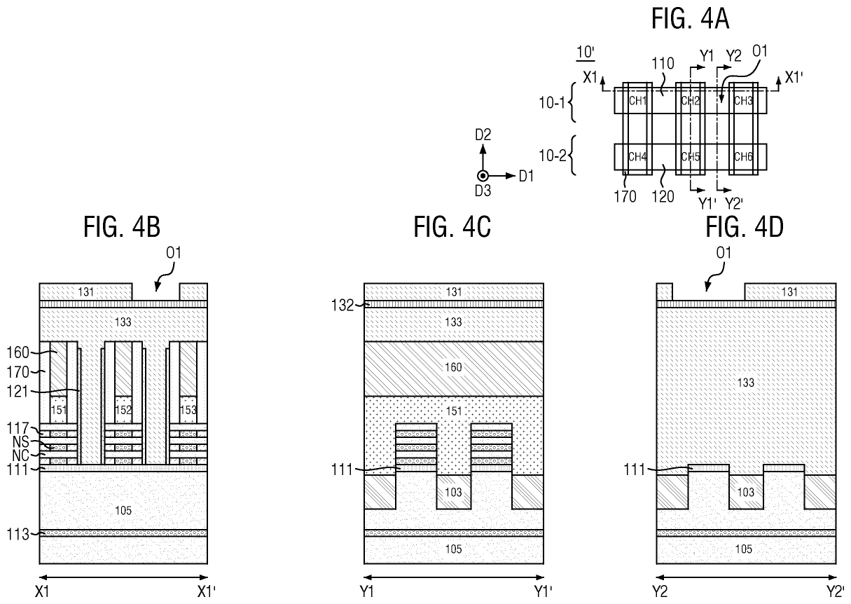

Referring to FIG. 4A-4D, thin protective liners 121 may be formed on side surfaces of the trenches T1 and T2, and a masking structure including a photoresist pattern 131, a silicon-containing anti-reflective coating (SiARC) layer 132, and an organic planarization layer (OPL) 133 may be prepared on the intermediate semiconductor device 10′.

A side surface of each of the trenches T1 and T2 on which a thin protective liner 121 is formed may include side surfaces of the inner spacer 117, the nanosheet layer NC and the gate spacer 170 which may be coplanar in the 3^{rd} direction D3. The thin protective liners 121 may be used to protect at least the inner spacer 117, the nanosheet layer NC and the gate spacer 170 in a later step of forming a placeholder structure for a backside contact structure in the substrate 105 below the two trenches T1 and T2 after removing the BDI layer 111 on the substrate 105. Thus, the thin protective liners 121 may be required to be formed of a material having etch selectivity against the BDI layer 111 and the substrate 105. The material forming the thin protective liners 121 may include at least one of silicon nitride, silicon oxynitride (SiON), silicon carbide (SiC), silicon carbon nitride (SiCN), not being limited thereto, different from the material included in the BDI layer 111.

The placeholder structure mentioned above will be formed in the substrate 105 to reserve a space for forming a backside contact structure, corresponding to the backside contact structure BC shown in FIGS. 1A-1E. The formation of the thin protective liners 121 may be performed through, for example, atomic layer deposition (ALD).

After the thin protective liners 121 are formed, a tri-layer patterning operation may be performed by filling the OPL 133 in the trenches T1 and T2 to cover the fin structures 110 and 120, forming the SiARC layer 132 on the OPL 133, and forming a photoresist pattern 131 on the SiARC layer 132. The OPL 133 may be formed of an organic polymer. Additionally or alternatively, the OPL 133 may include carbon, hydrogen, oxygen, nitrogen, fluorine, and/or silicon.

The photoresist pattern 131 may be formed on the SiARC layer 132 with a 1^{st} opening O1 to expose the SiARC layer 132 above the 2^{nd} trench T2 through which a placeholder structure for a backside contact structure is to be formed in a later step.

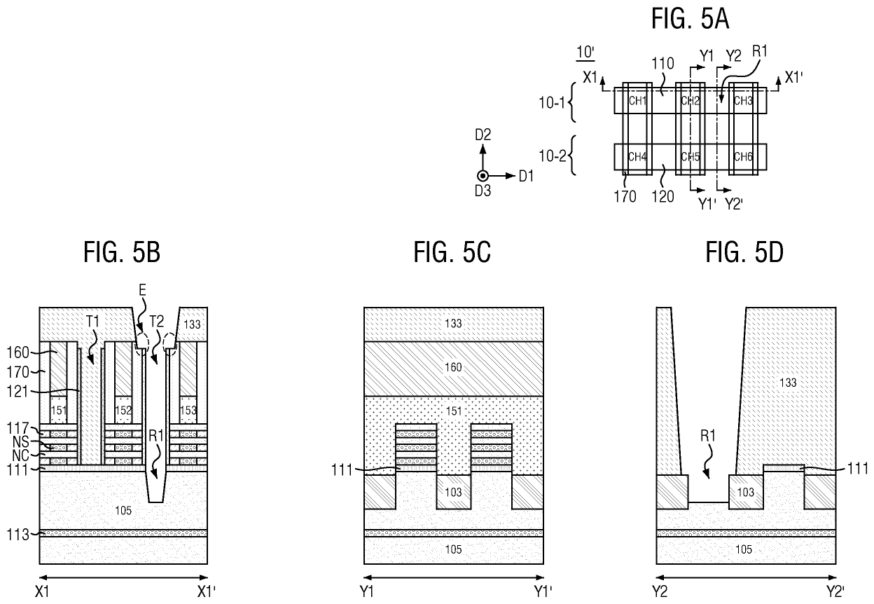

Referring to FIGS. 5A-5D, a portion of the OPL 133 filled in the 2^{nd} trench T2 below the 1^{st} opening O1, a portion of the BDI layer 111 below this portion of the OPL 133, and a portion of the substrate 105 of the portion of this BDI layer 111 may be patterned through, for example, dry etching and/or wet etching, based on the photoresist pattern 131.

At this time of the etching operation, top edge portions E of the gate spacer 170 and the thin protection liners 121 may be etched as the etching operation is performed in a self-aligned manner using etch selectivity between the material (e.g., organic polymer) forming the OPL 133 and the material (e.g., silicon nitride) forming the gate spacer 170 and the thin protection liners 121.

By this masking and etching operation in this step, a 1^{st} recess R1 may be formed in the substrate 105 below the 2^{nd} trench T2 to accommodate formation of a placeholder structure for a backside contact structure in a later step. The 1^{st} recess R1 may be formed in the substrate 105 below a level of the BDI layer 111, which is now removed, and above the etch stop layer 113. The formation of the 1^{st} recess R1 in the substrate 105 may be performed through, for example, dry etching, not being limited thereto.

The 1^{st} recess R1 may have a depth from a top surface of the substrate 105 to a level above the predetermined level from the bottom surface of the substrate 105 where the etch stop layer 113 is formed.

Before or after or before forming the 1^{st} recess R1 based on the photoresist pattern 131, the SiARC layer 132 and the photoresist pattern 131 may be removed by, for example, ashing or stripping.

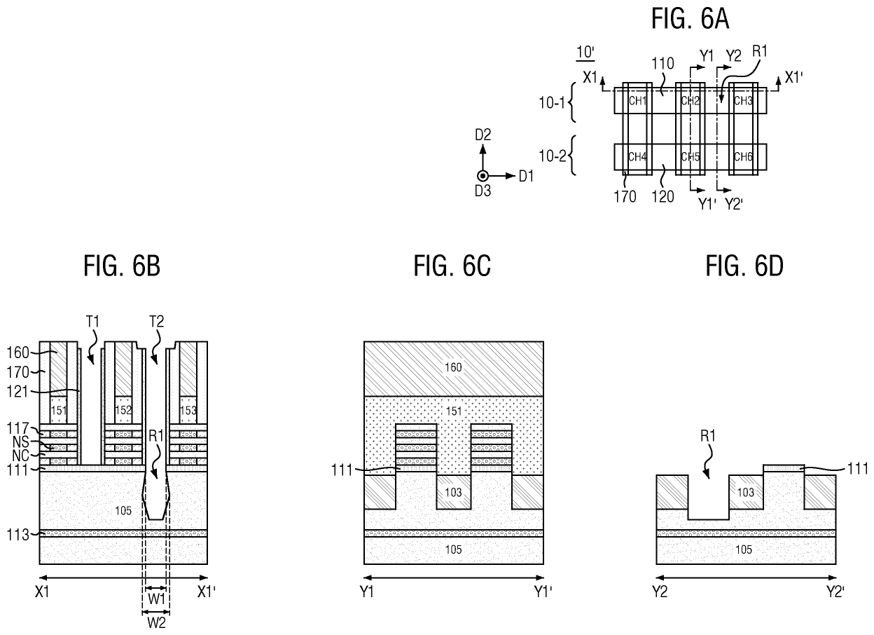

Referring to FIGS. 6A-6D, the OPL 133 used to form the 1^{st} recess R1 may be removed through, for example, an ashing operation to expose the gate hard mask structure 160. Further, additional etching may be performed on the 1^{st} recess R1 such that the 1^{st} recess R1 can have a 1^{st} predetermined shape. For example, the 1^{st} recess R1 after the additional etching may take a form of a hexagon (or trapezoid) in a cross-section view in the channel-length direction as shown in FIG. 6B while they may take a form of a rectangle in a cross-section view in the channel-width direction as shown in FIG. 6C. As another example, the 1^{st} recess R1 after the additional etching may take a form of the 1^{st} predetermined shape in at least one of a cross-section view in the channel-width direction and a cross-section view in the channel-length direction. The additional etching performed in this step may include sigma etching, according to an embodiment.

The hexagonal (or trapezoidal) shape has a positive slope and a negative slope, and thus, a top width W1 or a bottom width of the 1^{st} recess R1 may be smaller than a middle width W2 thereof. By forming the 1^{st} recess R1 in this shape, formation of a backside contact structure therein in the substrate 105 may be facilitated as will be described later.

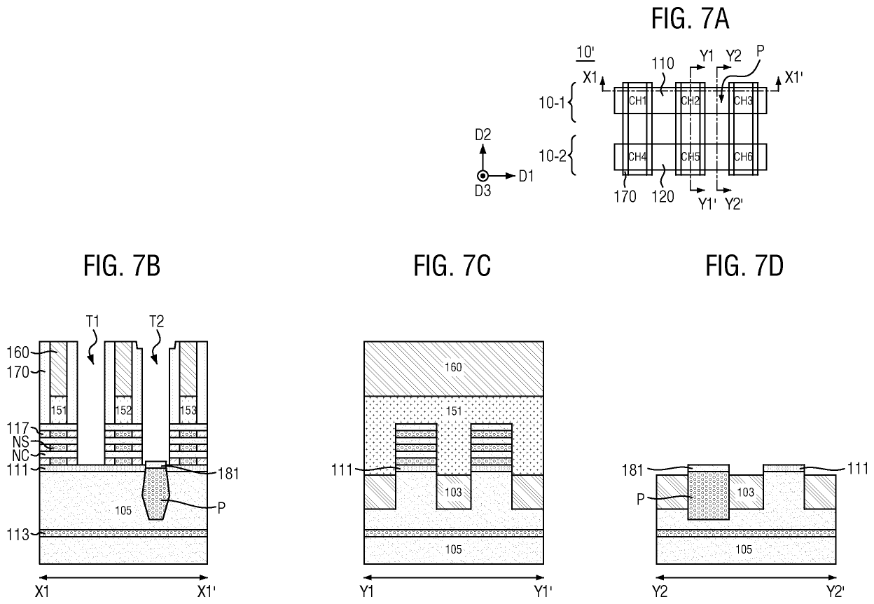

Referring to FIGS. 7A-7D, a placeholder structure P may be formed in the 1^{st} recess R1 through, for example, chemical vapor deposition (CVD), plasma enhanced CVD (PECVD), physical vapor deposition (PVD), atomic layer deposition (ALD), or a combination thereof, not being limited thereto.

As will be described later, the placeholder structures P may be formed to provide a space for formation of a backside contact structure connected to a bottom surface of a corresponding source/drain region in a semiconductor device to be formed in a later step. The placeholder structure P may be formed of silicon germanium (SiGe), for example, not being limited thereto.

According to an embodiment, a buffer layer 181 may be formed on a top surface of the placeholder structure P in the substrate 105. The buffer layer 181 may be formed through, for example, epitaxially growing silicon (Si) from the placeholder structure P or atomic layer deposition (ALD), not being limited thereto. The buffer layer 181 may an undoped semiconductor layer, according to an embodiment.

As will be described later, the buffer layer 181 may be used at least to prevent loss of an epitaxial structure forming a source/drain region formed thereabove when the placeholder structure P therebelow is removed to provide a space for a backside contact structure in a later step. Further, the buffer layer 181 may be used control an ohmic contact resistance of the source/drain region to be formed thereon in a next step.

After formation of the placeholder structure P and the buffer layer 181 thereon in the 2^{nd} trench T2, the thin protective liners 121 formed at the side surfaces of the trenches T1 and T2 may be removed though, for example, atomic layer etching (ALE). By removing the thin protective liners 121, side surfaces of the nanosheet layers NC, the inner spacer 117 and the gate spacer 170 may be exposed again through the trenches T1 and T2.

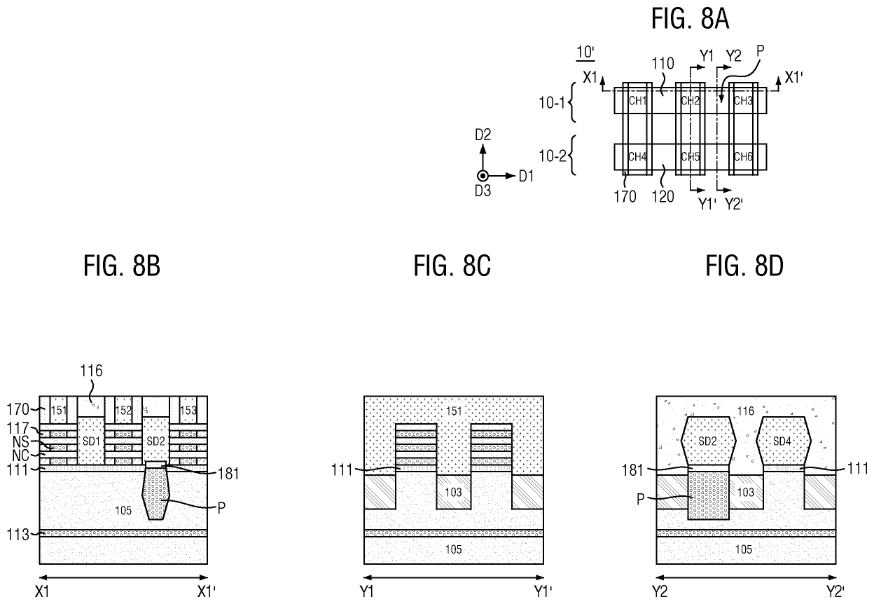

Referring to FIGS. 8A-8D, 1^{st} to 4^{th} source/drain regions SD1-SD4 may be epitaxially grown based on the 1^{st} to 6^{th} channel structures CH1-CH6.

The 1^{st} and 2^{nd} source/drain regions SD1 and SD2 may be epitaxially grown from the nanosheet layers NC of the 2^{nd} channel structure CH2 to form a nanosheet transistor in the 1^{st} semiconductor cell 10-1, and the 3^{rd} and 4^{th} source/drain regions SD3 and SD4 may be grown from the nanosheet layers NC of the 5^{th} channel structure CH5 to form a nanosheet transistor in the 2^{nd} semiconductor cell 10-2.

According to an embodiment, each of the 1^{st} to 4^{th} source/drain regions SD1-SD4 may be a p-type source/drain region including silicon germanium (SiGe), which may be the same as the material forming the placeholder structure P. This p-type source/drain region may be doped with p-type impurities such as boron (B), gallium (Ga), indium (In), etc. However, according to an embodiment, the 1^{st} and 2^{nd} source/drain regions SD1 and SD2 or the 3^{rd} and 4^{th} source/drain regions SD3 and SD4 may be an n-type source/drain region formed of silicon (Si) doped with impurities such as phosphorus (P), arsenic (As), antimony (Sb), etc.

Further, a 1^{st} isolation structure 116 may be formed on the intermediate semiconductor device 10′ to a level of top surfaces of the dummy gate structure 151, and the gate hard mask structure 160 and the gate spacer 170 formed on the side sides surfaces thereof may be removed.

The 1^{st} isolation structure 116 may include a material such as silicon oxide (e.g., SiO, SiO₂, etc.), not being limited thereto. The formation of the 1^{st} ILD structure 171 may be performed through, for example, CVD, PECVD, PVD, ALD or a combinations thereof, followed by an ashing or planarization operation such as chemical-mechanical polishing (CMP) to remove the gate hard mask structure 160 with the gate spacer 170 thereon, thereby exposing the dummy gate structures 151-153 upward.

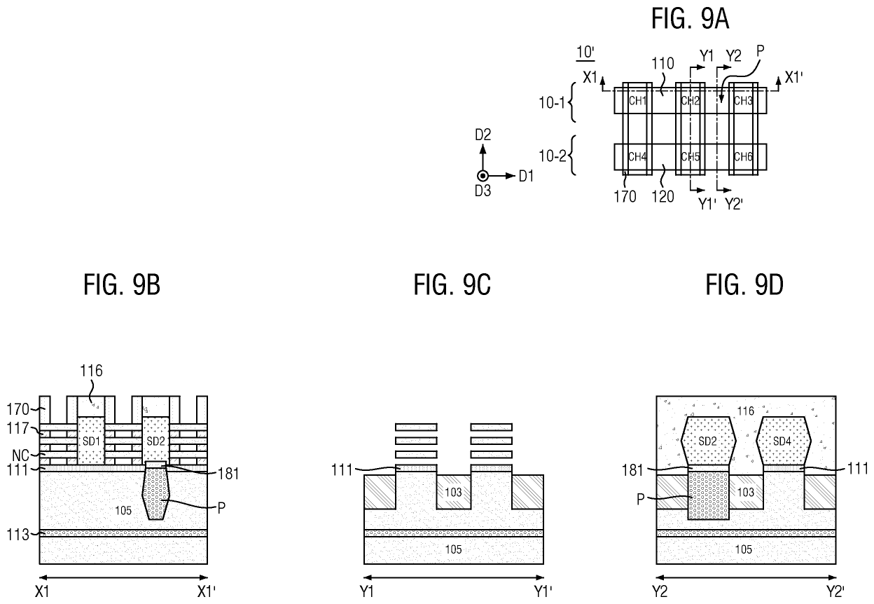

Referring to FIGS. 9A-9D, the dummy gate structures 151-153 may be removed along with the sacrificial layers NS included in the 1^{st} to 6^{th} channel structures CH1 to CH6. The removal operation in this step may include isotropic and/or anisotropic reactive ion etching (RIE), wet etching and/or a chemical oxide removal (COR) process, not being limited thereto. Thus, in the intermediate semiconductor device 10′, the nanosheet layers NC may be released from the sacrificial layers NS to form channel layers for nanosheet transistors to be formed in each of the semiconductor cells 10-1 and 10-2.

By this channel release operation, the nanosheet layers NC may be exposed through an open space where gate structures are to be formed in a subsequent step.

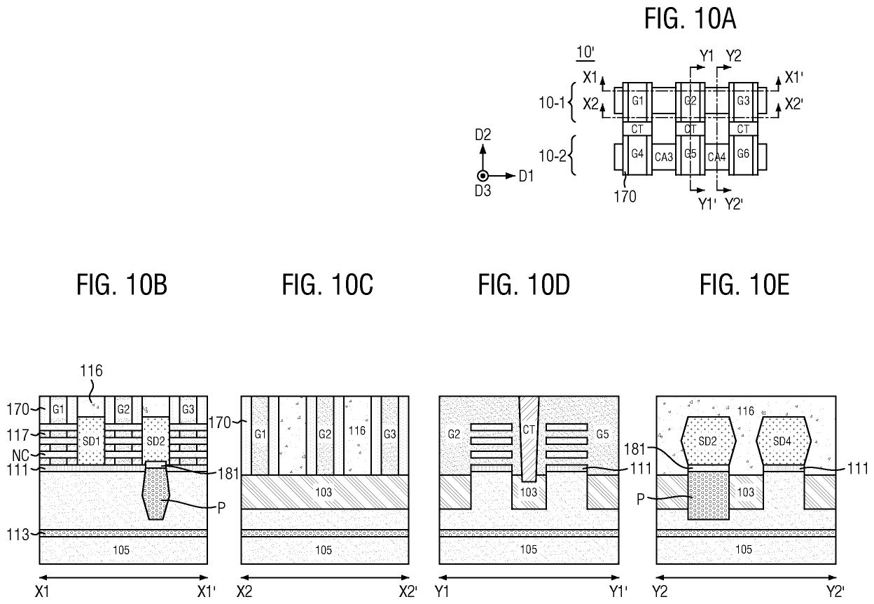

Referring to FIGS. 10A-10E, RMG structures may be formed in the spaces where the dummy gate structures 151′-153′ and the sacrificial layers NS are removed in the previous step, and a gate-cut structure CT may be formed in the RMG structures to divide the RMG structures into 1^{st} to 3^{rd} gate structures G1-G3 in the 1^{st} semiconductor cell 10-1 and 4^{th} to 6^{th} gate structures G4-G6 in the semiconductor cell 10-2.

By this RMG operation, the 1^{st} to 6^{th} gate structures G1-G6 may surround each of the nanosheet layers NC of the 1^{st} to 6^{th} channel structures CH1 to CH6, respectively.

Each of the gate structures G1-G6 may include a gate dielectric layer, a work-function layer, and a gate electrode. The gate dielectric layer formed on the nanosheet layers NC may include a dielectric material such as hafnium oxide (e.g., HfO₂). The work-function layer formed on the gate dielectric layer may include a material such as titanium (Ti), tantalum (Ta), etc., not being limited thereto. The gate electrode surrounding the work-function layer may include one or more metal components or metal compound including copper (Cu), aluminum (Al), tungsten (W), molybdenum (Mo), ruthenium (Ru), cobalt (Co), etc., not being limited thereto.

The formation of the RMG structures may be performed through, for example, atomic layer deposition (ALD), chemical vapor deposition (CVD), plasma enhanced CVD (PECVD), physical vapor deposition (PVD), or a combination thereof, not being limited thereto. The gate-cut structure CT may be performed through, for example, a photolithography and masking operation including dry etching, not being limited thereto.

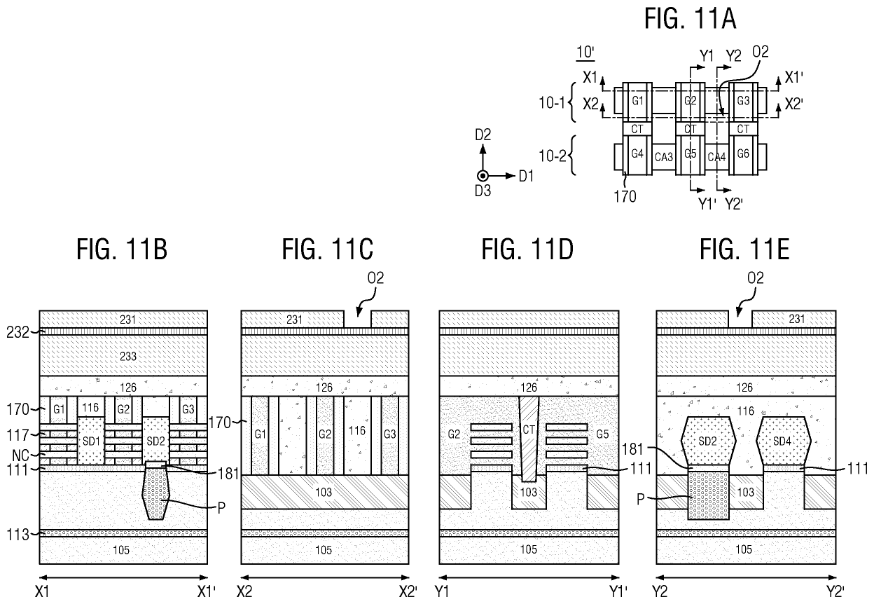

Referring to FIGS. 11A-11E, a 2^{nd} isolation structure 126 may be formed on the intermediate semiconductor device 10′ obtained in the previous step, and a masking structure including a photoresist pattern 231, an SiARC layer 232 and an OPL 233 may be prepared on the 2^{nd} isolation structure 126 for another tri-layer patterning operation.

The 2^{nd} isolation structure 126 may be formed above the gate structures G1-G6 and the source/drain regions SD1-SD4 to isolate front contact structures to be formed thereon from each other. The 2^{nd} isolation structure 126 may include a material such as silicon oxide (e.g., SiO, SiO₂, etc.), not being limited thereto. The 2^{nd} isolation structure 126 may be formed of a material the same as or similar to that of the 1^{st} isolation structure 116, and the formation of the 2^{nd} isolation structure 126 may be performed through, for example, CVD, PECVD, PVD, ALD or a combinations thereof.

The photoresist pattern 231 may be formed on the SiARC layer 232 with a 2^{nd} opening O2 to expose the SiARC layer 232 above a position where a portion of an enlarged backside contact structure is to be formed. This portion of the enlarged backside contact structure may correspond to the side via structure RV shown in FIGS. 1A-1E.

Referring to FIGS. 12A-12E, portions of the OPL 233, the 2^{nd} isolation structure 126, the 1^{st} isolation structure 116, and the STI structure 103 sequentially stacked vertically below the 2^{nd} opening O2 may be removed based on the photoresist pattern 231, thereby forming a 2^{nd} recess R2 penetrating through the isolation structures 126 and 116 to expose a top surface of the substrate 105 and one side surface of the 2^{nd} source/drain region SD2. The STI structure 103 may also be exposed at sides of the 2^{nd} recess R2.

According to an embodiment, the 2^{nd} recess R2 may also expose a side surface of the buffer layer 181 and a side surface of a portion of the placeholder structure P formed above the top surface of the substrate 105.

This masking and etching operation to form the 2^{nd} recess R2 in the isolation structures 126 and 116 may include dry etching and/or wet etching, not being limited thereto.

According to an embodiment, the masking and etching operation to form the 2^{nd} recess R2 may be performed such that a portion of the side surface of the 2^{nd} source/drain region SD2 is cut. Thus, the side surface of the 2^{nd} source/drain region SD2 exposed by the 2^{nd} recess R2 may be vertically plane, which is different from an opposite side thereof in the channel-width direction.

Before or after or before forming the 2^{nd} recess R2 based on the photoresist pattern 231, the SiARC layer 232 and the photoresist pattern 231 may be removed by, for example, ashing or stripping.

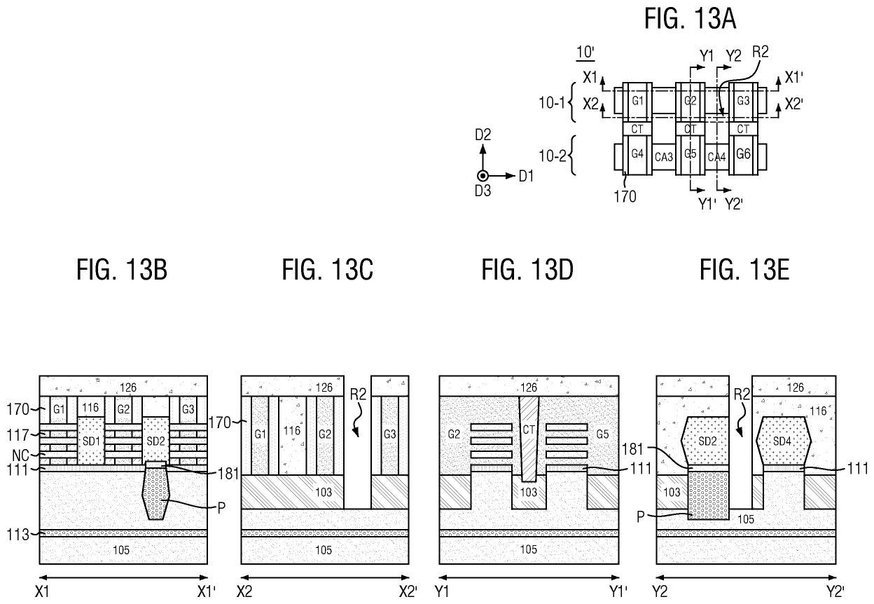

Referring to FIGS. 13A-13E, the OPL 233 used to form the 2^{nd} recess R2 may be removed through, for example, an ashing operation to expose a top surface of the 2^{nd} isolation structure 126, and the substrate 105 through the 2^{nd} recess R2.

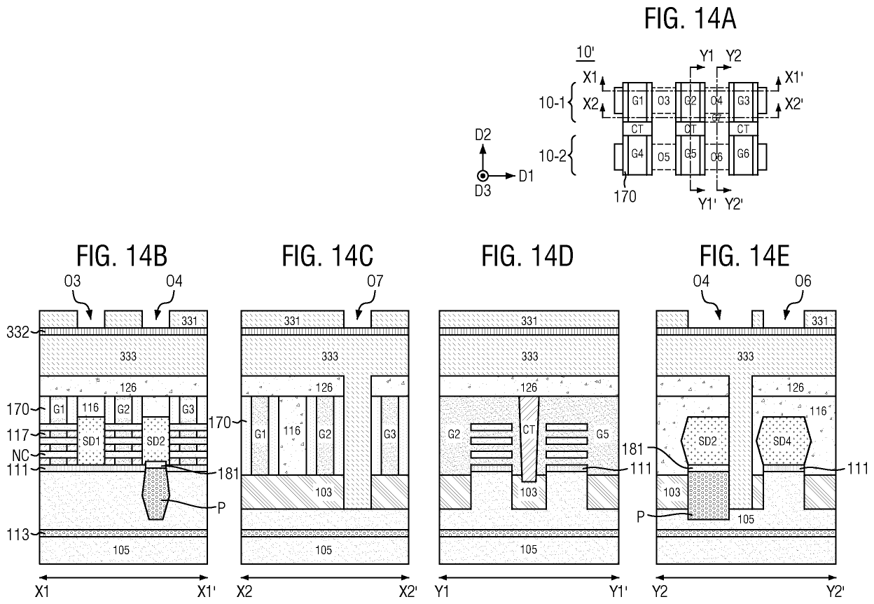

Referring to FIGS. 14A-14E, a masking structure including a photoresist pattern 331, an SiARC layer 332, and an OPL 333 may be prepared on the 2^{nd} isolation structure 126 for another tri-layer pattering operation.

The OPL 333 may be filled in the 2^{nd} recess R2, and the SiARC layer 332 may be formed thereon. Further, the photoresist pattern 331 may be formed on the SiARC layer 332 with 3^{rd} to 7^{th} openings O3-O7 to expose the SiARC layer 232 above positions where 1^{st} to 4^{th} front contact structures and a side via structure are to be formed. The 1^{st} to 4^{th} front contact structures and the side via structure may correspond to the 1^{st} to 4^{th} front contact structures CA1-CA4 and the side via structure RV shown in FIGS. 1A-1E.

Among the opening O3-O7, the 4^{th} opening O4 may correspond to the 2^{nd} front contact structure CA2 and the side via structure RV to form the enlarged backside contact structure as will be described herebelow.

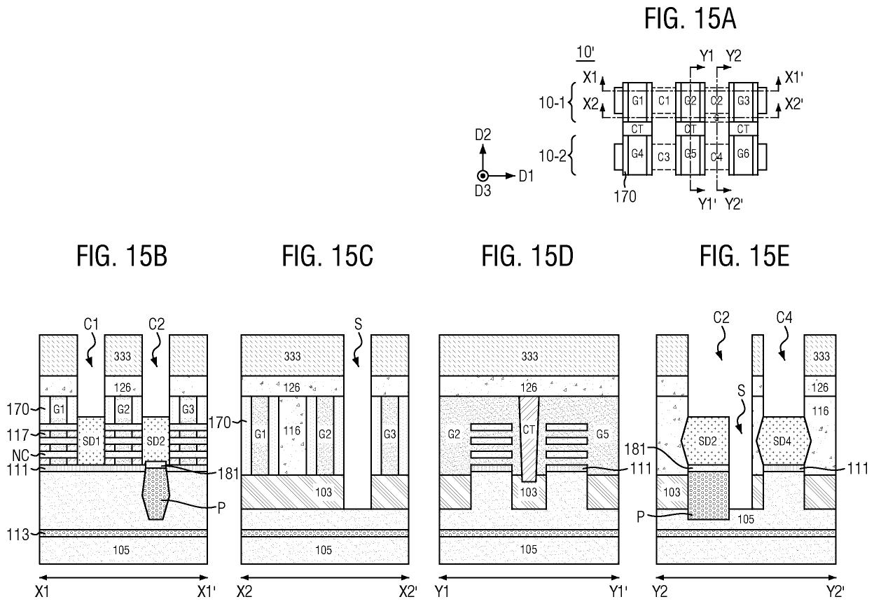

Referring to FIGS. 15A-15E, portions of the OPL 333, the 2^{nd} isolation structure 126, the 1^{st} isolation structure 116, and the STI structure 103 sequentially stacked vertically below the openings O3-O7 may be removed based on the photoresist pattern 331, thereby forming 1^{st} to 4^{th} contact recesses C1-C4 and a side via recess S, respectively.

This masking and etching operation to form the 1^{st} to 4^{th} contact recesses C1-C4 and the side via recess S in the isolation structures 126 and 116 may include dry etching and/or wet etching, not being limited thereto.

According to an embodiment, the masking and etching operation to form the 1^{st} to 4^{th} contact recesses C1-C4 and the side via recess S may be performed such that top surfaces of the 1^{st} to 4^{th} source/drain regions SD1-SD4 are open, and the 2^{nd} recess R2 formed in the previous step is open again.

Before or after or before forming 1^{st} to 4^{th} contact recesses C1-C4 and the side via recess S based on the photoresist pattern 331, the SiARC layer 232 and the photoresist pattern 331 may be removed by, for example, ashing or stripping.

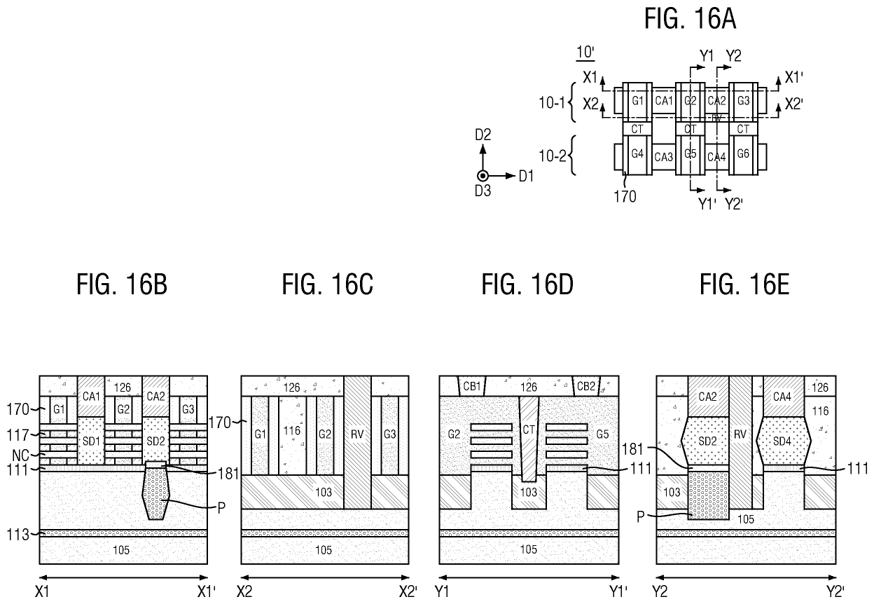

Referring to FIGS. 16A-16E, the 1^{st} to 4^{th} contact recesses C1-C4 and the side via recess S may be filled in with one or more metal components or metal compound including copper (Cu), aluminum (Al), tungsten (W), molybdenum (Mo), ruthenium (Ru), cobalt (Co), etc., not being limited thereto, followed by a chemical mechanical planarization (CMP) operation.

1^{st} to 4^{th} front contact structures CA1-CA4 and the side via structure RV may be formed on the 1^{st} to 4^{th} source/drain regions SD1-SD4, respectively. According to an embodiment, the 2^{nd} front contact structure CA2 and the side via structure RV may be connected to each other to form an enlarged backside contact structure in a later step.

According to an embodiment, the front contact structures CA1-CA4 may contact top surfaces of the source/drain regions SD1-SD4, respectively, and the side via structure RV may contact a side surface at a side of the channel-width direction of the 2^{nd} source/drain region SD2.

At this time, at least a 1^{st} and 2^{nd} gate contact structures CB1 and CB2 may also be formed on the gate structures G2 and G5, respectively, using the same or similar material in the same or similar method as the formation of the front contact structures CA1-CA4.

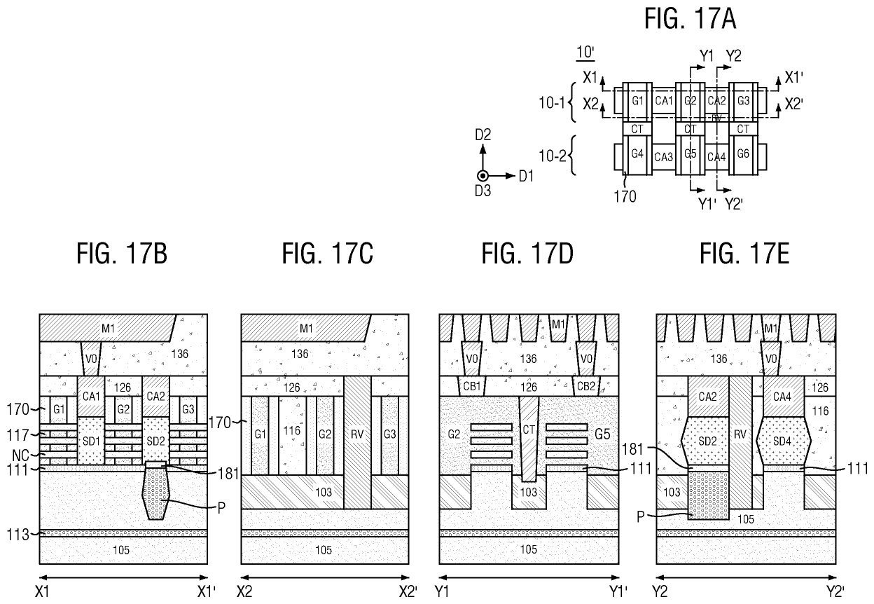

Referring to FIGS. 17A-17E, a 3^{rd} isolation structure 136 may be formed on the 2^{nd} isolation structure 126, and a plurality of via structures V0 and metal lines M1 may be formed in the 3^{rd} isolation structure 136 to be isolated from each other.

The via structures V0 and the metal lines M1 connect the front contact structures CA1, CA3 and CA4 and the gate contact structures CB1 and CB2 to a voltage source or another circuit element, respectively.

According to an embodiment, the 3^{rd} isolation structure 136 may be divided into an isolation structure isolating the via structures V0 from each other and another isolation structure isolating the metal lines M1 from each other.

The 3^{rd} isolation structure 136 may include a material such as silicon oxide (e.g., SiO, SiO₂, etc.), not being limited thereto. The formation of the isolation structure 136 may be performed through, for example, CVD, PECVD, PVD, ALD or a combinations thereof, and the formation of the via structures V0 and the metal lines M1 may be performed through, for example, photolithography and masking, dry etching and/or wet etching, and deposition such as CVD, PECVD, PVD, ALD or a combinations thereof.

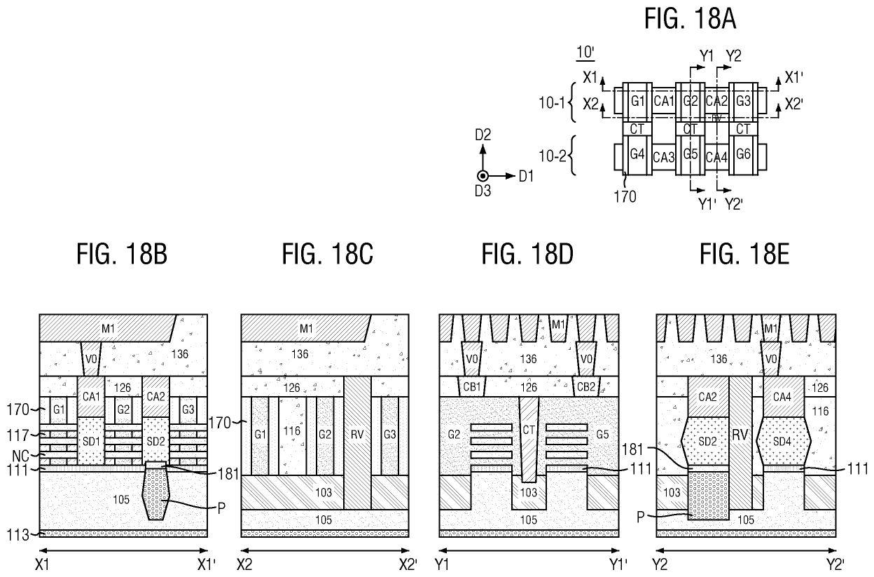

Referring to FIGS. 18A-18E, a portion of the substrate 105 may be removed through, for example, dry etching and/or planarization to expose the etch stop layer 113. It is understood here that, absent the etch stop layer 113 at the predetermined level from the bottom surface of the substrate 105, the dry etching and/or planarization may be excessive to remove even the placeholder structures P in the substrate 105. Thus, the etch stop layer 113, which may be formed of aluminum nitride (AlN) or silicon carbon nitride (SiCN), not being limited thereto, may prevent such excessive etching and/or planarization of the substrate 105.

According to an embodiment, the substrate removal operation in this step may be performed after the intermediate semiconductor device 10′ obtained in the previous step is flipped upside down based on a carrier wafer formed on the metal lines M1 to facilitate the substrate removal operation and subsequent etching/deposition operations.

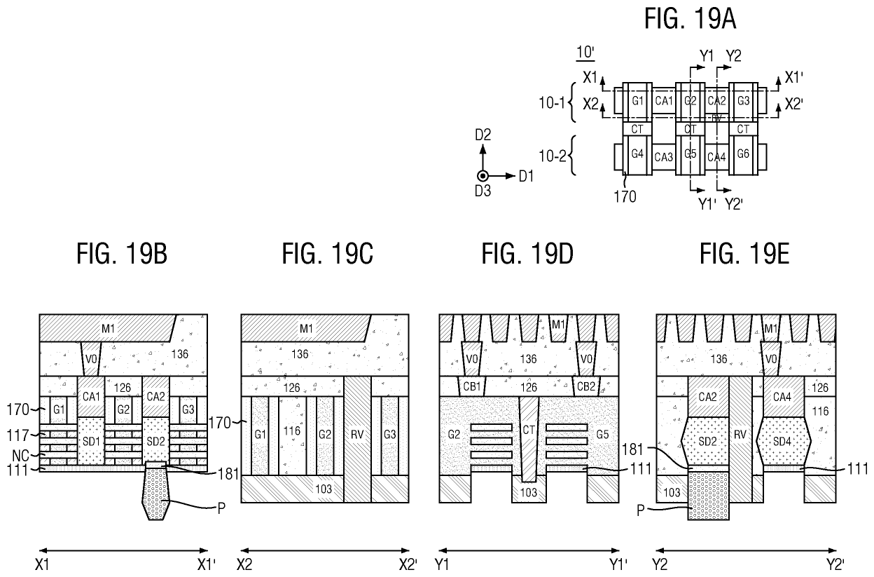

Referring to FIGS. 19A-19E, at least a portion of the substrate 105 may be removed from a back side of the intermediate semiconductor device 10′ leaving the placeholder structure P and the STI structure 103.

According to an embodiment, the substrate 105 may be removed in its entirety from the intermediate semiconductor device 10′.

As the substrate 105 is removed, the placeholder structure P, the STI structure 103, and the BDI layer 111 may be exposed to an outside. The substrate removal operation in this step may be performed through, for example, wet etching, not being limited thereto.

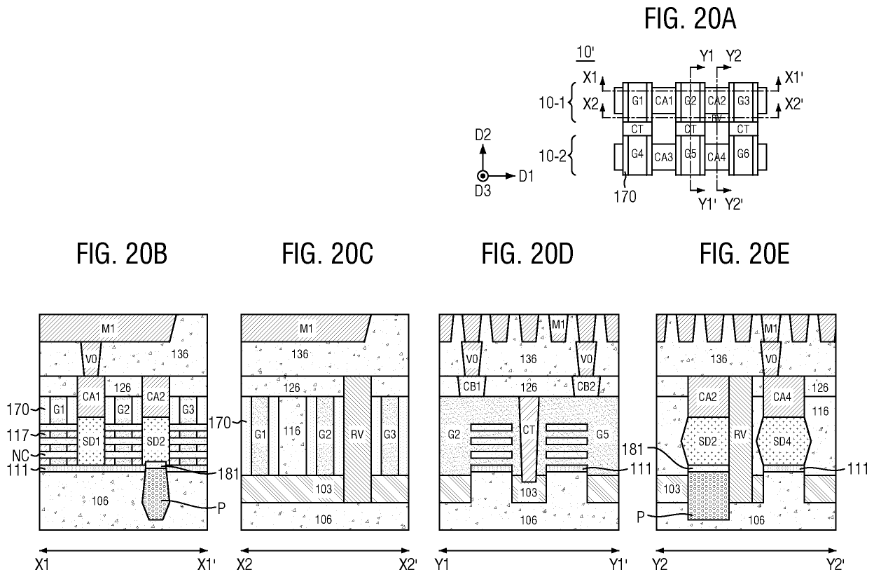

Referring to FIGS. 20A-20E, a backside isolation structure 106 may be formed at the back side of the intermediate semiconductor device 10′ obtained in the previous step to fill a space generated by the removal of the substrate 105, and enclose the placeholder structure P1 therein.

The backside isolation structure 106 may include a material such as silicon oxide (e.g., SiO, SiO₂, etc.), not being limited thereto. The formation of the backside isolation structure 106 may be performed through, for example, CVD, PECVD, PVD, ALD or a combinations thereof.

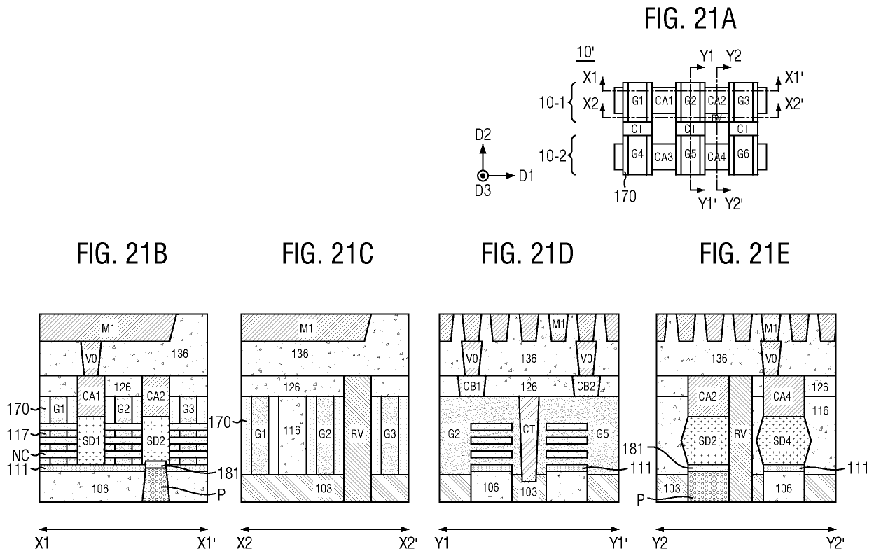

Referring to FIGS. 21A-21E, the back side of the intermediate semiconductor device 10′ may be planarized through, for example, a CMP operation such that the placeholder structure P may take a 2^{nd} predetermined shape such as a trapezoid having a positive slope at least in the cross-section view in the channel-length direction.

The planarization operation in this step may be performed to remove a portion of the placeholder structure P having a negative slope such that the placeholder structure P can have the 2^{nd} predetermined shape having a positive slope. This planarization operation may be performed in order to facilitate deposition of a metal or a metal compound for a backside contact structure in a space obtained by removing the placeholder structure P in a later step.

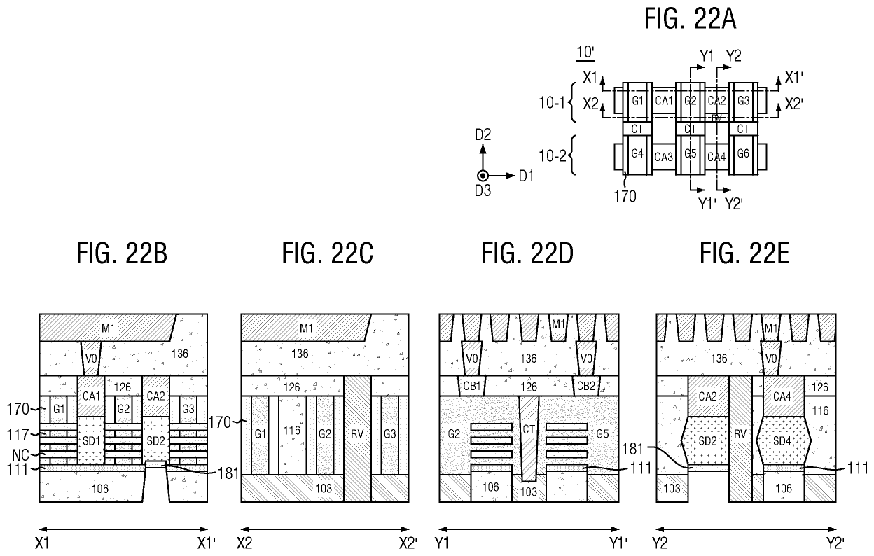

Referring to FIGS. 22A-22E, the placeholder structure P may be extracted through, for example, wet etching against the backside isolation structure 106 and the STI structure 103 to expose the buffer layer 181 formed thereon and a side surface of a portion of the side via structure RV and a side surface of the STI structure 103.

The buffer layer 181 formed of a material such as silicon (Si) may protect the 2^{nd} source/drain region SD2 formed thereon when the placeholder structure P is removed. For example, without the buffer layer 181, when the 2^{nd} source/drain region SD2 is a p-type source/drain region formed of silicon germanium (SiGe), wet etching applied to the placeholder structure P which may also be formed of silicon germanium (SiGe) may also etch the 2^{nd} source/drain region SD2.

However, this buffer layer 181 may not have been formed on the placeholder structure P in the earlier step (FIGS. 7A-7) when the 2^{nd} source/drain region SD2 is formed of not silicon germanium (SiGe) but silicon (Si). This is because when the placeholder structure P formed of silicon germanium (SiGe) is wet-etched, loss of silicon (Si) forming the 2^{nd}source/drain regions SD2 formed of silicon (Si) may be avoided or minimized even without the buffer layers 181 due to etch selectivity between the two materials.

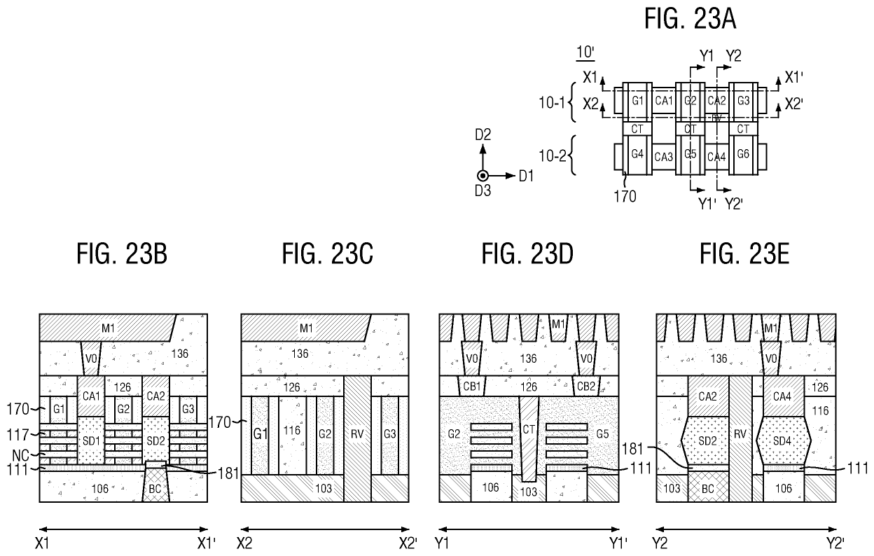

Referring to FIGS. 23-23, a backside contact structure BC may be formed in a space left from the removal of the placeholder structure P.

As the backside contact structure BC replaces the placeholder structure P, the backside contact structure BC may be connected to a bottom surface of the 2^{nd} source/drain region SD2 with the buffer layer 181 therebetween. Further, the backside contact structure BC may contact the side surface of a portion of the side via structure RV.

Thus, the backside contact structure BC may become an enlarged backside contact structure by being combined with the side via structure RV which contacts a side surface of the 2^{nd} front contact structure CA2.

The formation of the backside contact structure BC may be performed through, for example, CVD, PVD, PECVD, ALD and their combination thereof, not being limited thereto. Here, since the space left from the removal of the placeholder structure P may have the 2^{nd} predetermined shape such as a trapezoid having a positive slope, deposition of the backside contact structure PC in this space may be fully self-aligned when the formation of the backside contact structure BC is performed when the intermediate semiconductor device 10′ is flipped upside down.

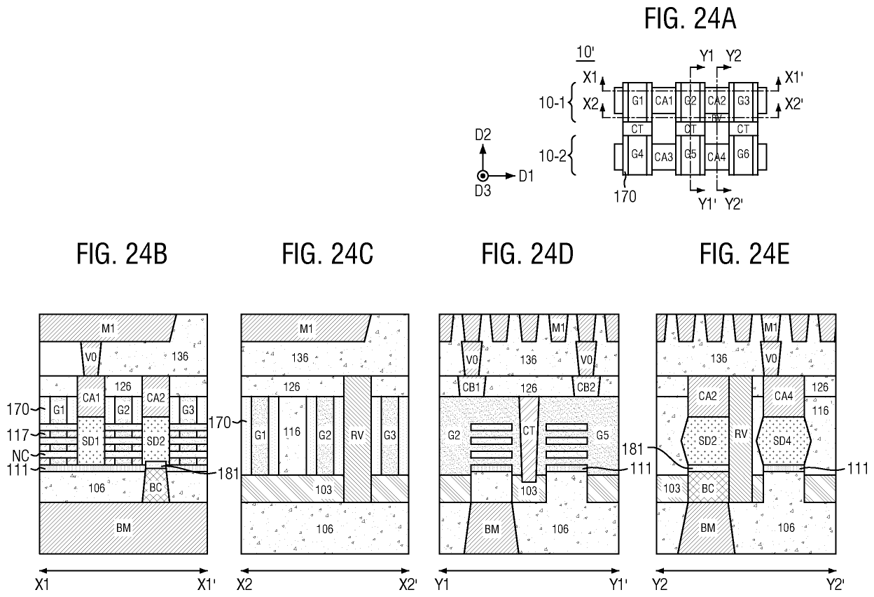

Referring to FIGS. 24A-24E, an additional isolation structure may be formed on bottom surfaces of the backside isolation structure 106, the backside contact structure BC and the STI structure 103 to enlarge the backside isolation structure 106, and a backside metal line BM may be formed therein.

The backside metal line BM may be a backside power rail connected to a voltage source, for example, in which case the 2^{nd} source/drain region SD2 may be powered through the backside contact structure BC and the backside metal line BM.

Thus, the intermediate semiconductor device 10′ may be completed as a semiconductor device, corresponding to the semiconductor device 10 shown in FIGS. 1A-1E, including a plurality of nanosheet transistors in which an enlarged backside contact structure is formed on a source/drain region.

It is understood here that the same method of manufacturing the semiconductor device 10 shown in FIGS. 1A-1E may apply to manufacturing the semiconductor device 20 shown in FIGS. 2A-2E, except that two side via recesses need to be formed at both sides of the 2^{nd} source/drain region SD2, the buffer layer 181 and the placeholder structure P in FIGS. 11A-11E to 15A-15E so that the two side via structure RV1 and RV2 can be formed in the two side via recesses. Duplicate descriptions are omitted herein.

In the meantime, the above embodiments are described for manufacturing a semiconductor device including a plurality of nanosheet transistors. However, the disclosure may not be limited thereto but may also apply to a semiconductor device including different types of field-effect transistor such as a FinFET.

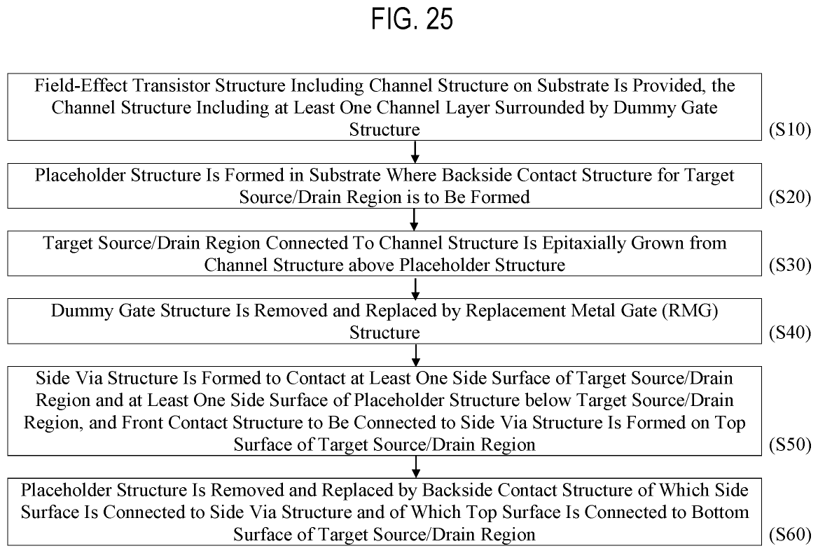

FIG. 25 is a flowchart illustrating a method of manufacturing a semiconductor device including a plurality of field-effect transistors in which an enlarged backside contact structure is formed on a source/drain region, according to embodiments.

In operation S10, a field-effect transistor structure including a channel structure on a substrate may be provided, the channel structure including at least one channel layer surrounded by a dummy gate structure.

The channel structure may include a plurality of nanosheet layers for a nanosheet transistor or vertical fin structures for a FinFET, not being limited thereto. The channel structures may also include sacrificial layers respectively formed below or above the nanosheet layers in case of formation of the nanosheet transistor.

In operation S20, a placeholder structure may be formed in the substrate where a backside contact structure for a target source/drain region is to be formed.

To form the placeholder structure, the substrate may be etched down from top to a predetermined distance to form a recess in the substrate, and a material such as silicon germanium (SiGe) may be filled in the recess.

After the placeholder structure is formed, a buffer layer may be epitaxially grown from the placeholder structure. The buffer layer may be formed of a material such as silicon (Si).

In operation S30, the target source/drain region connected to the channel structure may be epitaxially grown from the channel structure above the placeholder structure.

In operation S40, the dummy gate structure may be removed and replaced by a replacement metal gate (RMG) structure.

When the dummy gate structure is removed, the sacrificial layers may also be removed, and the RMG structure may replace the sacrificial layers as well as the dummy gate structure.

In operation S50, a side via structure may be formed to contact at least one side surface of the target source/drain region and at least one side surface of the placeholder structure below the target source/drain region, and a front contact structure to be connected to the side via structure may be formed on a top surface of the target source/drain region.

To form the side via structure and the front contact structure, an isolation structure surrounding the target source/drain region may be etched to provide respective recesses therein, and a metal or a metal compound may fill in the recesses.

In operation S60, the placeholder structure may be removed and replaced by a backside contact structure of which a side surface is connected to the side via structure and of which a top surface is connected to a bottom surface of the target source/drain region.

When the placeholder structure is removed, the buffer layer may prevent a material loss of the target source/drain region formed thereabove.

To form the backside contact structure, the field-effect transistor structure may be flipped upside down to fill a metal or a metal compound in a space obtained by removing the placeholder structure.

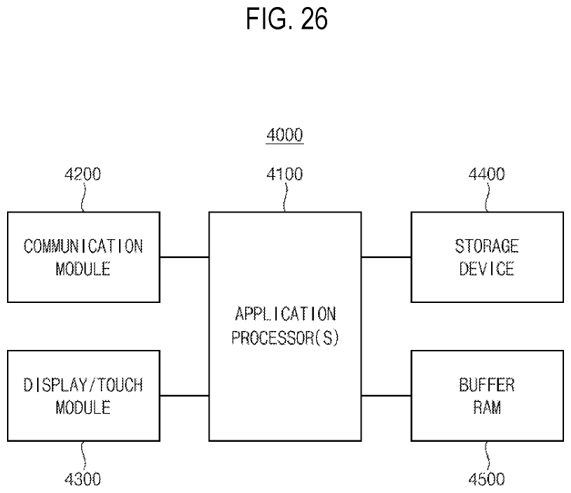

FIG. 26 is a schematic block diagram illustrating an electronic device including a plurality of field-effect transistors in which an enlarged backside contact structure is formed on a source/drain region, as shown in FIGS. 1A-1E or FIGS. 2A-2E, according to an example embodiment.

Referring to FIG. 26, an electronic device 4000 may include at least one application processor 4100, a communication module 4200, a display/touch module 4300, a storage device 4400, and a buffer random access memory (RAM) 4500. The electronic device 4000 may be a mobile device such as a smartphone or a tablet computer, not being limited thereto, according to embodiments.

The application processor 4100 may control operations of the electronic device 4000. The communication module 4200 is implemented to perform wireless or wire communications with an external device. The display/touch module 4300 is implemented to display data processed by the application processor 4100 and/or to receive data through a touch panel. The storage device 4400 is implemented to store user data. The storage device 4400 may be an embedded multimedia card (eMMC), a solid state drive (SSD), a universal flash storage (UFS) device, etc. The storage device 4400 may perform caching of the mapping data and the user data as described above.

The buffer RAM 4500 may temporarily store data used for processing operations of the electronic device 4000. For example, the buffer RAM 4500 may be volatile memory such as double data rate (DDR) synchronous dynamic random access memory (SDRAM), low power double data rate (LPDDR) SDRAM, graphics double data rate (GDDR) SDRAM, Rambus dynamic random access memory (RDRAM), etc.

The electronic device 4000 may further include at least one sensor such as an image sensor.

At least one component in the electronic device 4000 may include the semiconductor device in FIGS. 1A-1E or FIGS. 2A-2E.

The foregoing is illustrative of example embodiments and is not to be construed as limiting the disclosure. Although some example embodiments have been described above, those skilled in the art will readily appreciate that many modifications are possible in the above embodiments without materially departing from the disclosure.

What is claimed is:

1. A semiconductor device comprising:
a channel structure;
a 1^{st} source/drain region on the channel structure; and
an enlarged backside contact structure connected to the 1^{st} source/drain region,
wherein the enlarged backside contact structure comprises a backside contact structure below the 1^{st} source/drain region, a 1^{st} side via structure at a 1^{st} side of the 1^{st} source/drain region, and a 1^{st} front contact structure above the 1^{st} source/drain region, and
wherein the backside contact structure is connected to the 1^{st} side via structure, which is connected to the front contact structure.

2. The semiconductor device further comprising:
a 2^{nd} source/drain region on the channel structure; and
a 2^{nd} front contact structure connected to the 2^{nd} source/drain region, above the 2^{nd} source/drain region.

3. The semiconductor device of claim 2, wherein a shape of the 1^{st} source/drain region is different from a shape of the 2^{nd} source/drain region.

4. The semiconductor device of claim 1, wherein the backside contact structure is connected to a bottom surface of the 1^{st} source/drain region, the 1^{st} side via structure is connected to a 1^{st} side surface of the 1^{st} source/drain region, and the front contact structure is connected to a top surface of the 1^{st} source/drain region.

5. The semiconductor device of claim 2, further comprising a buffer layer between the 1^{st} source/drain region and the backside contact structure,
wherein the 1^{st} source/drain region comprises a different material component from that of the buffer layer.

6. The semiconductor device of claim 5, wherein the 1^{st} source/drain region comprises silicon germanium (SiGe) and the buffer layer comprises silicon (Si).

7. The semiconductor device of claim 2, wherein the 1^{st} side surface of the 1^{st} source/drain region is vertically plane.

8. The semiconductor device of claim 1, wherein the enlarged backside contact structure further comprises a 2^{nd} side via structure at a 2^{nd} side, opposite to the 1^{st} side, of the 1^{st} source/drain region, and
wherein the 2^{nd} side via structure is connected to a 2^{nd} side surface, opposite to the 1^{st} side surface, of the 1^{st} source/drain region.

9. The semiconductor device of claim 8, wherein the 2^{nd} side via structure is connected to the 1^{st} front contact structure and the backside contact structure.

10. The semiconductor device of claim 9, wherein the 2^{nd} side surface of the 1^{st} source/drain region is vertically plane.

11. A semiconductor device comprising:
a channel structure:
a 1^{st} source/drain region on the channel structure; and
an enlarged backside contact structure connected to the 1^{st} source/drain region,
wherein the enlarged backside contact structure contacts at least a bottom surface and a 1^{st} side surface of the 1^{st} source/drain region.

12. The semiconductor device of claim 11, wherein the enlarged backside contact structure further contacts a top surface of the 1^{st} source/drain region.

13. The semiconductor device of claim 12, wherein the enlarged backside contact structure contacts a 2^{nd} side surface, opposite to the 1^{st} side surface, of the 1^{st} source/drain region.

14. The semiconductor device of claim 11, further comprising:
a 2^{nd} source/drain region on the channel structure; and
a 2^{nd} front contact structure connected to the 2^{nd} source/drain region, above the 2^{nd} source/drain region.

15. The semiconductor device of claim 14, wherein a shape of the 1^{st} source/drain region is different from a shape of the 2^{nd} source/drain region.

16. A method of manufacturing a semiconductor device:
providing a channel structure on a substrate;
forming a placeholder structure in the substrate at a position where a source/drain region is to be formed thereabove;
forming the source/drain region above the placeholder structure;
forming a 1^{st} side via structure contacting a 1^{st} side surface of the source/drain region; and
replacing the placeholder structure with a backside contact structure contacting a bottom surface of the source/drain region, and connected to the 1^{st} side via structure.

17. The method of claim 16, further comprising forming a front contact structure contacting a top surface of the source/drain region, and connected to the 1^{st} side via structure.

18. The method of claim 17, wherein the front contact structure is formed in a separate step after the formation of the 1^{st} side via structure.

19. The method of claim 16, further comprising forming a 2^{nd} side via structure contacting a 2^{nd} side surface, opposite to the 1^{st} surface, of the source/drain region.

20. The method of claim 17, further comprising forming a front contact structure contacting a top surface of the source/drain region, and connected to the 1^{st} side via structure and the 2^{nd} side via structure.
